(19) United States
(12) Patent Application Publication
(10) Pub. No.: US 2025/0336873 A1
(43) Pub. Date: Oct. 30, 2025

(54) BACK-TO-BACK THREE-DIMENSIONAL STACKED FAN-OUT PACKAGING STRUCTURE AND PREPARATION METHOD THEREOF, BACK-TO-BACK THREE-DIMENSIONAL STACKED FAN-OUT PACKAGING MODULE AND PREPARATION METHOD THEREOF

(71) Applicant: INSTITUTE OF SEMICONDUCTORS, GUANGDONG ACADEMY OF SCIENCES, Guangzhou (CN)

(72) Inventors: Yingqiang YAN, Guangzhou (CN); Chuan HU, Guangzhou (CN); Wei ZHAO, Guangzhou (CN); Xun XIANG, Guangzhou (CN)

(21) Appl. No.: 19/027,737

(22) Filed: Jan. 17, 2025

(30) Foreign Application Priority Data
Apr. 30, 2024 (CN) 202410547024.2

(51) Int. Cl. H01L 23/00; H01L 23/49; H01L 25/07

(52) U.S. Cl. CPC H01L 24/25; H01L 23/49; H01L 24/24; H01L 24/82; H01L 25/074; H01L 2224/2401; H01L 2224/24146; H01L 2224/244; H01L 2224/2518; H01L 2224/82005; H01L 2224/82101; H01L 2224/82801

(57) ABSTRACT

Disclosed is a back-to-back three-dimensional stacked fan-out packaging structure and a preparation method thereof, and also a packaging module utilizing the packaging structure and a preparation method thereof. The solution provided by the present invention does not require chip TSV stacking, and the stacked chips may be electrically connected in the shortest vertical interconnection manner, thereby ensuring a high interconnection density and transmission performance while reducing packaging costs and improving packaging yield.

### CROSS-REFERENCE TO RELATED APPLICATION

This application claims the priority of Chinese patent application No. 202410547024.2, filed on Apr. 30, 2024, which application is hereby incorporated herein by reference.

### FIELD OF THE INVENTION

The present invention relates to a technical field of integrated circuit packaging technology, and more particularly relates to a back-to-back three-dimensional stacked fan-out packaging structure and a preparation method thereof, and a back-to-back three-dimensional stacked fan-out packaging module and a preparation method thereof.

### BACKGROUND OF THE INVENTION

With the advancement of technology, the volume of data transmission is becoming increasingly vast, which consequently raises the demand for larger storage capacities in electronic devices. This is constrained by data storage, retrieval, and transmission speeds. To meet the requirements for high data transmission capabilities and large storage capacities, it is also necessary for memory to have high bandwidth and low power consumption. To enhance memory bandwidth, the industry currently often employs 3D stacked bonding packaging processes to create the packaging structures of memory chips.

In the 3D stacked bonding packaging process, chip stacking is a common form of packaging. It involves stacking multiple chips through bonding to form a chip package structure with higher interconnect density and performance. In chip stacking packaging processes, interconnecting the stacked chips through TSV (Through Silicon Via) technology is a prevalent method for achieving inter-chip interconnections. However, this approach typically requires the preparation of through silicon vias (TSV) and copper pillars on the chips, which complicates the process, reduces packaging yield, and relies on expensive materials such as NCF (Non-Conductive Film) or NCP (Non-Conductive Paste) and TCB bonders (Thermo-compression Bonders), leading to very high process costs. Additionally, the chip stacking bonding speed is extremely slow, and the overall packaging efficiency is low. For example, in TSMC's typical CoWoS packaging technology, although it can realize high-bandwidth interconnections between CPUs or GPUs and HBM (High Bandwidth Memory), the packaging process involves stacking HBM through TSV technology, then using TCB technology to flip-chip mount CUP/GPU and a TSV stack of the HBM onto an interposer, and subsequently using TCB technology to flip-chip mount the entire assembly onto a carrier board. However, it can be seen that this packaging method requires repeated use of TCB (Thermo-compression Bonding) technology, making the process complex and costly. Moreover, since CoWoS packages the TSV stack and CUP/GPU on the same side using TCB technology, and the HBM memory and CPU are on the same side, the memory can only be placed around the CPU, resulting in poor space utilization. This leads to large package sizes and low integration, making it difficult to meet the ever-growing demand for high storage capacity. Additionally, CoWoS packaging requires the interposer with HBM stacks and CUP/GPU to be flip-chip mounted onto the carrier board, which limits the line width and spacing of interconnects and increases their length, thus affecting interconnect density and transmission performance.

Furthermore, for packaged devices with stacked packages, the mutual stacking of multiple layers of chips can lead to heat dissipation challenges, which in turn affects transmission efficiency between the chips.

### SUMMARY OF THE INVENTION

The embodiments of the present invention provide a new back-to-back three-dimensional stacked fan-out packaging structure that does not require chip TSV stacking, and the stacked chips may realize electrical connectivity through the shortest vertical interconnection method, thereby further reducing packaging costs and improving packaging yields while ensuring high interconnection density and transmission performance.

In a first aspect, an embodiment of the present invention provide a back-to-back three-dimensional stacked fan-out packaging structure, comprising:
at least one set of stacked chips, each set of stacked chips comprising at least one chip with a functional surface facing a first direction and at least one chip with a functional surface facing a second direction, wherein the first direction and the second direction are opposite directions;
s packaging material layer, encapsulating the stacked chips;
a first redistribution layer, positioned on one side of the packaging material layer and electrically connected to the chip with the functional surface facing the first direction;
a second redistribution layer, positioned on the other side of the packaging material layer and electrically connected to the chip with the functional surface facing the second direction;
a vertical interconnect conductive structure for electrically connecting the first redistribution layer and the second redistribution layer, wherein at least a partial section of the vertical interconnect conductive structure is disposed in the packaging material layer.

In a second aspect, an embodiment of the present invention provide a back-to-back three-dimensional stacked fan-out packaging module, comprising:
a packaging carrier board, wherein the packaging carrier board is the back-to-back three-dimensional stacked fan-out packaging structure as described in the first aspect, and the packaging carrier board includes at least two sets of stacked chips;
a flip chip, wherein the flip chip is disposed on at least a portion of the redistribution conductive structure of the first redistribution layer or the second redistribution layer of the packaging carrier board and electrically connected to the corresponding redistribution conductive structure; and
solder balls or external pins that are disposed on the first redistribution layer or the second redistribution layer and electrically connected to at least a portion of the redistribution conductive structure thereof.

In a third aspect, an embodiment of the present invention provide another back-to-back three-dimensional stacked fan-out packaging module, comprising:
a packaging carrier board, wherein the packaging carrier board is the back-to-back three-dimensional stacked fan-out packaging structure as described in the first aspect, including at least two sets of stacked chips;
a fine line adapter board disposed on the first redistribution layer or the second redistribution layer of the packaging carrier board, wherein the fine line adapter board is electrically connected to the corresponding redistribution layer;
a flip chip, wherein the flip chip is disposed on the fine line adapter board and electrically connected to the fine line adapter board; and
solder balls or external pins disposed on the redistribution layer without the fine line adapter board and electrically connected to at least a portion of the redistribution conductive structure.

In a fourth aspect, an embodiment of the present invention provide a preparation method for a back-to-back three-dimensional stacked fan-out packaging structure, comprising:
performing chip stacking on one surface of a temporary carrier board to form at least one set of stacked chips, wherein each set of stacked chips includes at least one chip with a functional surface facing a first direction and at least one chip with a functional surface facing a second direction, wherein the first direction and second direction are opposite directions, and the different chips are stacked and adhered together via a stacking material;
performing encapsulation on a side of the temporary carrier where the stacked chips are mounted with packaging material to form a packaging material layer that encapsulates the stacked chips;
preparing a conductive structure on the packaging material layer, wherein the conductive structure includes a first conductive structure that is electrically connected to the chip with the functional surface facing the first direction and a vertical interconnect conductive structure that penetrates through the packaging material layer;
removing the temporary carrier board, exposing chip surfaces that were covered by the temporary carrier board to a surface of the packaging material layer; and
preparing a first redistribution layer that is electrically connected to the chip facing the first direction and a second redistribution layer that is electrically connected to the chip facing the second direction on both surfaces of the packaging material layer, wherein the first redistribution layer is electrically connected to the chip facing the first direction through the first conductive structure, the second redistribution layer is directly electrically connected to the chip facing the second direction, and the first redistribution layer and second redistribution layer are electrically connected through the vertical interconnect conductive structure.

In a fifth aspect, an embodiment of the present invention provide another preparation method for a back-to-back three-dimensional stacked fan-out packaging structure, comprising:
preparing a support insulating material and a first vertical conductive structure penetrating through the support insulating material on one surface of a temporary carrier board, wherein the support insulating material defines a recessed chip attachment region;
performing chip stacking on the chip attachment region of the temporary carrier board to form at least one set of stacked chips, wherein each set of stacked chips includes at least one chip with a functional surface facing a first direction and at least one chip with a functional surface facing a second direction, wherein the first direction and second direction are opposite directions, and the different chips are stacked and adhered together through a stacking material;
performing encapsulation on a side of the temporary carrier board where the stacked chips are mounted with packaging material to form a packaging material layer that encapsulates the stacked chips;
preparing conductive structures on the packaging material layer, wherein the conductive structures include a first conductive structure that is electrically connected to the chip with the functional surface facing the first direction and a second vertical conductive structure that is vertically interconnected to the first vertical conductive structure, wherein the first vertical conductive structure and the second vertical conductive structure together form a vertical interconnect conductive structure;
removing the temporary carrier board, exposing chip surfaces that were covered by the temporary carrier board to a surface of the packaging material layer; and
preparing a first redistribution layer that is electrically connected to the chip facing the first direction and a second redistribution layer that is electrically connected to the chip facing the second direction on both surfaces of the packaging material layer, wherein the first redistribution layer is electrically connected to the chip facing the first direction through the first conductive structure, the second redistribution layer is directly electrically connected to the chip facing the second direction, and the first redistribution layer and second redistribution layer are electrically connected through the vertical interconnect conductive structure.

In a sixth aspect, an embodiment of the present invention provide yet another preparation method for a back-to-back three-dimensional stacked fan-out packaging structure, comprising:
performing chip stacking on one surface of a support structure to form at least one set of stacked chips, wherein each set of stacked chips includes at least one chip with a functional surface facing a first direction and at least one chip with a functional surface facing a second direction, wherein the first direction and second direction are opposite directions, and the different chips are stacked and adhered together through a stacking material;
performing encapsulation on a side of the support structure where the stacked chips are mounted with packaging material to form a packaging material layer that encapsulates the stacked chips;
preparing a first conductive structure on the packaging material layer that is electrically connected to the chip facing the first direction;
preparing a vertical interconnect conductive structure that penetrates through the packaging material layer and the support structure;
preparing a first redistribution layer on the packaging material layer that is electrically connected to the chip facing the first direction, wherein the first redistribution layer is electrically connected to the chip facing the first direction through the first conductive structure;
preparing a second conductive structure on the support structure that is electrically connected to the chip with the functional surface facing the second direction; and
preparing a second redistribution layer on the support structure that is electrically connected to the first redistribution layer through the vertical interconnect conductive structure and is electrically connected to the chip with the functional surface facing the second direction through the second conductive structure.

In a seventh aspect, an embodiment of the present invention provide yet another preparation method for a back-to-back three-dimensional stacked fan-out packaging structure, comprising:
pre-preparing support a support insulating material on one surface of the permanent carrier board, wherein the support insulating material defines a recessed chip attachment region;
preparing a first vertical conductive structure penetrating through the support insulating material and the permanent carrier board on one surface of the support structure;
performing chip stacking on the chip attachment region of the permanent carrier board to form at least one set of stacked chips, wherein each set of stacked chips includes at least one chip with a functional surface facing a first direction and at least one chip with a functional surface facing a second direction, wherein the first direction and second direction are opposite directions, and the different chips are stacked and adhered together through a stacking material;
performing encapsulation on a side of the permanent carrier board where the stacked chips are mounted with packaging material to form a packaging material layer that encapsulates the stacked chips;
preparing a first conductive structure on the packaging material layer that is electrically connected to the chip facing the first direction;
preparing on the permanent carrier board a first redistribution layer that is electrically connected to the chip facing the first direction,
preparing a second vertical conductive structure that is vertically interconnected to the first vertical conductive structure, wherein the first vertical conductive structure and the second vertical conductive structure together form a vertical interconnect conductive structure;
preparing a first redistribution layer on the packaging material layer that is electrically connected to the chip facing the first direction, wherein the first redistribution layer is electrically connected to the chip facing the first direction through the first conductive structure;
preparing a second conductive structure on the support structure that is electrically connected to the chip with the functional surface facing the second direction;
preparing a second redistribution layer on the permanent carrier board that is electrically connected to the first redistribution layer through the vertical interconnect conductive structure and is electrically connected to the chip with the functional surface facing the second direction through the second conductive structure.

In an eighth aspect, an embodiment of the present invention provide yet another preparation method for yet another back-to-back three-dimensional stacked fan-out packaging structure, comprising:
preparing a fine interconnect layer on one surface of a temporary carrier board;
performing chip stacking on the fine interconnect layer to form at least one set of stacked chips, wherein each set of stacked chips includes at least one chip with a functional surface facing a first direction and at least one chip with a functional surface facing a second direction, wherein the first direction and second direction are opposite directions, the different chips are stacked and adhered together through a stacking material, and the chip closest to the fine interconnect layer is adhered to the fine interconnect layer through an adhesive material;
performing encapsulation on a side of the temporary carrier board where the stacked chips are mounted with packaging material to form a packaging material layer that encapsulates the stacked chips;
preparing a first conductive structure on the packaging material layer that is electrically connected to the chip facing the first direction;
preparing a vertical interconnect conductive structure that penetrates through the packaging material layer, the adhesive material and the fine interconnect layer;
removing the temporary carrier board, exposing the fine interconnect layer that was covered by the temporary carrier board to the surface of the packaging material layer;
preparing a first redistribution layer on the packaging material layer that is electrically connected to the chip facing the first direction, wherein the first redistribution layer is electrically connected to the chip facing the first direction through the first conductive structure;
preparing a second conductive structure on the adhesive material and the fine interconnect layer that is electrically connected to the chip with the functional surface facing the second direction;
preparing a second redistribution layer on the fine interconnect layer that is electrically connected to the first redistribution layer through the vertical interconnect conductive structure and electrically connected to the fine interconnect layer and the chip with the functional surface facing the second direction through the second conductive structure.

In a ninth aspect, an embodiment of the present invention provide yet another preparation method for a back-to-back three-dimensional stacked fan-out packaging structure, comprising:
preparing a fine interconnect layer on one surface of a temporary carrier board;
performing chip stacking on the fine interconnect layer to form at least one set of stacked chips, wherein each set of stacked chips includes at least one chip with a functional surface facing a first direction and at least one chip with a functional surface facing a second direction, wherein the first direction and second direction are opposite directions, the different chips are stacked and adhered together through a stacking material, and the chip closest to the fine interconnect layer is adhered to the fine interconnect layer through an adhesive material;
performing encapsulation on a side of the temporary carrier board where the stacked chips are mounted with a packaging material to form a packaging material layer that encapsulates the stacked chips;
preparing a first conductive structure on the packaging material layer that is electrically connected to the chip facing the first direction;
preparing a vertical interconnect conductive structure that penetrates through the packaging material layer, the adhesive material, and the fine interconnect layer;
removing the temporary carrier board, exposing the fine interconnect layer that was covered by the temporary carrier board to the surface of the packaging material layer;
preparing a first redistribution layer on the packaging material layer that is electrically connected to the chip facing the first direction, wherein the first redistribution layer is electrically connected to the chip facing the first direction through the first conductive structure;
preparing a second conductive structure on the adhesive material and the fine interconnect layer that is electrically connected to the chip with the functional surface facing the second direction;
preparing a second redistribution layer on the fine interconnect layer that is electrically connected to the first redistribution layer through the vertical interconnect conductive structure and electrically connected to the fine interconnect layer and the chip with the functional surface facing the second direction through the second conductive structure.

In a tenth aspect, an embodiment of the present invention provide a preparation method for a back-to-back three-dimensional stacked fan-out packaging structure, comprising:
preparing a fine interconnect layer on one surface of a permanent carrier board;
performing chip stacking on the fine interconnect layer to form at least one set of stacked chips, wherein each set of stacked chips includes at least one chip with a functional surface facing a first direction and at least one chip with a functional surface facing a second direction, wherein the first direction and second direction are opposite directions, the different chips are stacked and adhered together through a stacking material, and the chip closest to the fine interconnect layer is adhered to the fine interconnect layer through an adhesive material;
performing encapsulation on a side of the permanent carrier board where the stacked chips are mounted with a packaging material to form a packaging material layer that encapsulates the stacked chips;
preparing a first conductive structure on the packaging material layer that is electrically connected to the chip facing the first direction;
preparing a vertical interconnect conductive structure that penetrates through the packaging material layer, the adhesive material, the fine interconnect layer and the permanent carrier board;
preparing a first redistribution layer on the packaging material layer that is electrically connected to the chip facing the first direction, wherein the first redistribution layer is electrically connected to the chip facing the first direction through the first conductive structure;
preparing a second conductive structure on the adhesive material, the fine interconnect layer and the permanent carrier board that is electrically connected to the chip with the functional surface facing the second direction;
preparing a second redistribution layer on the fine interconnect layer that is electrically connected to the first redistribution layer through the vertical interconnect conductive structure and electrically connected to the fine interconnect layer and the chip with the functional surface facing the second direction through the second conductive structure.

In a eleventh aspect, an embodiment of the present invention provide a preparation method for a back-to-back three-dimensional stacked fan-out packaging structure, comprising:
preparing a fine interconnect layer on one surface of the permanent carrier board
pre-preparing a support insulating material on the fine interconnect layer to define a recessed chip attachment region through the support insulating material;
preparing a first vertical conductive structure that penetrates the support insulating material, the fine interconnect layer and the permanent carrier board;
performing chip stacking on the chip attachment region of the fine interconnect layer to form at least one set of stacked chips, wherein each set of stacked chips includes at least one chip with a functional surface facing the first direction and at least one chip with a functional surface facing the second direction, with the first direction and the second direction being opposite directions, and different chips are stacked and adhered together through a stacking material;
performing encapsulation on a side of the permanent carrier board where the stacked chips are mounted with a packaging material to form a packaging material layer that encapsulates the stacked chips;
preparing a first conductive structure on the packaging material layer that is electrically connected to the chip with a functional surface facing the first direction;
preparing a second vertical conductive structure on the packaging material layer that is vertically interconnected to the first vertical conductive structure, with the first vertical conductive structure and the second vertical interconnect conductive structure together forming the vertical interconnect conductive structure;
preparing a first redistribution layer on the packaging material layer that is electrically connected to the chip with a functional surface facing the first direction, wherein the first redistribution layer is electrically connected to the chip with a functional surface facing the first direction through the first conductive structure;
preparing a second conductive structure that penetrates the permanent carrier board, the adhesive material and the fine interconnect layer, electrically connecting with the chip with a functional surface facing the second direction;
preparing a second redistribution layer on the fine interconnect layer that is electrically connected to the first redistribution layer through the vertical interconnect conductive structure and simultaneously connects with the fine interconnect layer and the chip with a functional surface facing the second direction through the second conductive structure.

In a twelfth aspect, an embodiment of the present invention provide a preparation method for a back-to-back three-dimensional stacked fan-out packaging structure, comprising:
preparing a back-to-back three-dimensional stacked fan-out packaging structure as a packaging carrier board through any said method of the present invention, wherein the prepared packaging carrier board includes at least two sets of stacked chips;
preparing, on the first redistribution layer and/or the second redistribution layer of the packaging carrier board, packaging external connection pin pads that are electrically connected to at least a portion of the redistribution conductive structure thereof;
flip-chip soldering a flip chip pre-prepared with pad bumps on at least some of the packaging external connection pin pads and preparing solder balls or external pins on the other packaging external connection pin pads.

In a thirteenth aspect, an embodiment of the present invention provide a preparation method for a back-to-back three-dimensional stacked fan-out packaging structure, comprising:
preparing a back-to-back three-dimensional stacked fan-out packaging structure as a packaging carrier board through any said method of the present invention, wherein the prepared packaging carrier board includes at least two sets of stacked chips;
preparing, on the first redistribution layer and the second redistribution layer of the packaging carrier board, packaging external connection pin pads that are electrically connected to at least a portion of the redistribution conductive structure thereof;
flip-chip soldering a fine line adapter board, which is electrically connected to the corresponding packaging external connection pin pads, on the packaging external connection pin pads of the first redistribution layer or the second redistribution layer of the packaging carrier board;
flip-chip soldering a flip chip pre-prepared with pad bumps on the fine line adapter board, wherein the flip chip is electrically connected to the first or second redistribution layer through the fine line adapter board; and
preparing solder balls or external pins on the packaging external connection pin pads on the redistribution layer that does not have the fine line adapter board.

The advantageous effects of the embodiments of the present invention are that: the solution provided by the embodiment of present invention includes at least one set of stacked chips within a packaging structure, wherein each set of stacked chips comprises at least one chip with a functional surface facing a first direction and at least one chip with a functional surface facing a second direction. Therefore, the packaging structure of the embodiment of present invention is capable of performing interconnection wiring in two different directions, which, compared to a packaging structure that can only perform interconnection wiring in one direction, reduces the number of chips interconnected in a single direction. This allows for a higher wiring space for the interconnection of a single chip, thus enabling a higher wiring density for interconnections with a single chip. Additionally, this also significantly increases the total number of chips that can be integrated within the packaging structure, effectively enhancing the integration level of the packaging structure. Furthermore, the solution of the present invention realizes electrical interconnection between chips in the packaging structure by electrically interconnecting the first redistribution layer, which is arranged in the first direction, with the chip facing the first direction, by electrically interconnecting the second redistribution layer, which is arranged in the second direction, with the chip facing the second direction, and by electrically connecting the first redistribution layer and the second redistribution layer through a vertical interconnection conductive structure, which is at least partially arranged in the packaging material layer and extends in the thickness direction of the packaging material. This approach avoids the need to create vertical interconnection conductive channels using TSV technology on the chips, thereby reducing packaging costs and effectively improving packaging yield. Moreover, by electrically connecting chips facing different directions to the redistribution layers arranged in the corresponding directions, vertical interconnection of stacked chips in the Z-axis direction based on different directions can be realized, shortening the length of the interconnection lines and increasing the spatial utilization of the stacked chips in the XY plane. This effectively reduces the size of the packaging structure, allowing for the integration of more chips within the same size packaging structure, thereby enhancing the performance of the packaging structure. Additionally, the solution of the present invention, when packaging stacked chips, can avoid the use of expensive materials such as NCF or NCP for filling and the use of costly TCB equipment for debonding, further simplifying the packaging process steps for stacked chips and reducing packaging costs. Furthermore, since the packaging structure produced by the three-dimensional stacking method of the present invention can integrate the required chips (including chip functions and chip quantities) according to demand, and since high-density interconnection can be realized between chips through the first conductive structure, the vertical interconnection conductive structure, and the rerouting layers, the preparation cost is low. The resulting packaging structure possesses high transmission bandwidth and transmission rate, making it suitable for widespread application in memory devices. In addition, in the embodiments of the present invention that include a supporting structure, the supporting structure contains only the vertical interconnection conductive structure and does not require the fabrication of interconnection lines. Therefore, the process for the supporting structure is simple and cost-effective. Due to these characteristics of the supporting structure in embodiments of the present invention, in preferred implementations, the supporting structure may be fabricated using thicker thermally conductive materials, such as metals (copper, aluminum, etc.), ceramics (alumina, aluminum nitride, silicon carbide, etc.), or composite materials (various double-sided copper-clad laminates used in the printed circuit board industry), which provide better heat dissipation compared to HBM packaging and wire bonding packaging processes. Moreover, for HBM packaging, the packaging process must repeatedly use temporary bonding, TSV, and TCB. However, the preparation process of embodiments of the present invention, when applied to HBM memory packaging, does not require the use of TSV stacking methods for the stacked memory chips, and it can completely avoid the use of temporary bonding and TCB techniques. This also eliminates the need for expensive temporary bonding materials and temporary bonding carriers used in HBM packaging processes, thereby reducing costs. Additionally, the solution of the present invention can also avoid using TCB for flip-chip bonding in packaging that includes flip chips, and the flip chips and stacked chips can be arranged in a stacked manner in the Z direction (either above or below the flip chips), thus allowing for higher spatial utilization of the XY surface of the packaging module and supporting larger stacked chip capacities, particularly in scenarios requiring large-capacity memory. At the same time, the packaging structure of embodiments of the present invention can directly serve as the packaging substrate for the packaging module without the need for an additional packaging substrate, thereby shortening the length of the interconnection lines between the stacked chips and the flip chips, and also reducing the number of bonding steps. Taking CoWoS packaging as an example, in addition to the need for bonding between the stacked chips, it also requires the stacked chips and the CPU to be flipped onto an adapter board and then the adapter board along with the chips to be flipped onto a dedicated packaging substrate, necessitating multiple temporary bonding and debonding steps. However, in the preparation method of embodiments of the present invention, aside from the bonding of the stacked chips, only one flip chip bonding is required. Even in embodiments that include an adapter board, only two flip chip bondings are needed, resulting in lower costs while also allowing for larger memory capacity and bandwidth.

### BRIEF DESCRIPTION OF THE DRAWINGS

In order to more clearly illustrate the technical solutions of the embodiments of the present invention, drawings needed to be used in the description of the embodiments will be briefly described below. Obviously, the drawings in the following description are some examples of the present invention. For a person having ordinary skill in the art, other drawings can be obtained based on these drawings without exerting creative efforts.

FIG. 1 schematically illustrates a vertical cross-sectional view of a back-to-back three-dimensional stacked fan-out packaging structure according to an embodiment of the present invention;

FIG. 2 schematically illustrates a vertical cross-sectional view of a back-to-back three-dimensional stacked fan-out packaging structure according to another embodiment of the present invention;

FIG. 3 schematically illustrates a vertical cross-sectional view of a back-to-back three-dimensional stacked fan-out packaging structure according to yet another embodiment of the present invention;

FIG. 4 schematically illustrates a vertical cross-sectional view of a back-to-back three-dimensional stacked fan-out packaging structure according to a further embodiment of the present invention;

FIG. 5 schematically illustrates a vertical cross-sectional view of a back-to-back three-dimensional stacked fan-out packaging structure according to an embodiment of the present invention;

FIG. 6 schematically illustrates a vertical cross-sectional view of a back-to-back three-dimensional stacked fan-out packaging structure according to an embodiment of the present invention;

FIG. 7 schematically illustrates a vertical cross-sectional view of a back-to-back three-dimensional stacked fan-out packaging structure according to an embodiment of the present invention;

FIG. 8 schematically illustrates a vertical cross-sectional view of a back-to-back three-dimensional stacked fan-out packaging structure according to an embodiment of the present invention;

FIG. 9 schematically illustrates a vertical interconnect packaging structure according to an embodiment of the present invention, where FIG. 9(a) is a vertical cross-sectional view of the vertical interconnect packaging structure, and FIG. 9(b) is a top view of the vertical interconnect packaging structure;

FIG. 10 schematically illustrates a vertical cross-sectional view of a back-to-back three-dimensional stacked fan-out packaging module according to an embodiment of the present invention;

FIG. 11 schematically illustrates a vertical cross-sectional view of a back-to-back three-dimensional stacked fan-out packaging module according to an embodiment of the present invention;

FIG. 12 schematically illustrates a vertical cross-sectional view of a back-to-back three-dimensional stacked fan-out packaging module according to an embodiment of the present invention;

FIG. 13 schematically illustrates a vertical cross-sectional view of a back-to-back three-dimensional stacked fan-out packaging module according to an embodiment of the present invention;

FIG. 14 schematically illustrates a vertical cross-sectional view of a back-to-back three-dimensional stacked fan-out packaging module according to an embodiment of the present invention;

FIG. 15 schematically illustrates a vertical cross-sectional view of a back-to-back three-dimensional stacked fan-out packaging module according to an embodiment of the present invention;

FIG. 16 schematically illustrates a flowchart of the preparation method for a back-to-back three-dimensional stacked fan-out packaging structure according to an embodiment of the present invention;

FIG. 17 schematically illustrates a cross-sectional view of an intermediate structure corresponding to the preparation process of a back-to-back three-dimensional stacked fan-out packaging structure according to an embodiment of the present invention;

FIG. 18 schematically illustrates a flowchart of the preparation method for a back-to-back three-dimensional stacked fan-out packaging structure according to an embodiment of the present invention;

FIG. 19 schematically illustrates a cross-sectional view of an intermediate structure corresponding to the preparation process of a back-to-back three-dimensional stacked fan-out packaging structure according to an embodiment of the present invention;

FIG. 20 schematically illustrates a flowchart of the preparation method for a back-to-back three-dimensional stacked fan-out packaging structure according to another embodiment of the present invention;

FIG. 21 schematically illustrates a cross-sectional view of an intermediate structure corresponding to the preparation process of a back-to-back three-dimensional stacked fan-out packaging structure according to some embodiments;

FIG. 22 schematically illustrates a flowchart of the preparation method for a back-to-back three-dimensional stacked fan-out packaging structure according to some embodiments;

FIG. 23 schematically illustrates a flowchart of the preparation method for a back-to-back three-dimensional stacked fan-out packaging structure according to yet another embodiment of the present invention;

FIG. 24 schematically illustrates a cross-sectional view of an intermediate structure corresponding to the preparation process of a back-to-back three-dimensional stacked fan-out packaging structure according to some embodiments;

FIG. 25 schematically illustrates a cross-sectional view of an intermediate structure corresponding to the preparation process of a back-to-back three-dimensional stacked fan-out packaging structure according to another embodiment of the present invention;

FIG. 26 schematically illustrates a flowchart of the preparation method for a back-to-back three-dimensional stacked fan-out packaging structure according to yet another embodiment of the present invention;

FIG. 27 schematically illustrates a cross-sectional view of an intermediate structure corresponding to the preparation process of a back-to-back three-dimensional stacked fan-out packaging structure according to yet another embodiment of the present invention;

FIG. 28 schematically illustrates a flowchart of the preparation method for a back-to-back three-dimensional stacked fan-out packaging structure according to an embodiment of the present invention;

FIG. 29 schematically illustrates a cross-sectional view of an intermediate structure corresponding to the preparation process of a back-to-back three-dimensional stacked fan-out packaging structure according to another embodiment of the present invention;

FIG. 30 schematically illustrates a flowchart of the preparation method for a back-to-back three-dimensional stacked fan-out packaging structure according to an embodiment of the present invention;

FIG. 31 schematically illustrates a flowchart of the preparation method for a back-to-back three-dimensional stacked fan-out packaging module according to some embodiments; and

FIG. 32 schematically illustrates a flowchart of the preparation method for a back-to-back three-dimensional stacked fan-out packaging module according to yet another embodiment of the present invention.

### DETAILED DESCRIPTION OF THE PREFERRED EMBODIMENTS

In order to make the purpose, technical solutions and advantages of the embodiments of the present invention clearer, the technical solutions in the embodiments of the present invention will be clearly and completely described below in conjunction with the drawings in the embodiments of the present invention. Obviously, the described embodiments are part of the embodiments of the present invention rather than all of the embodiments. Based on the embodiments of the present invention, all other embodiments obtained by a person having ordinary skill in the art without creative efforts fall within the scope of protection of the present invention.

It should be noted that, as long as there is no conflict, the embodiments and features in the embodiments of the present invention can be combined with each other.

It should also be noted that the terms used in the present invention are typically terms commonly used by a person having ordinary skill in the art. If they are inconsistent with commonly used terms, the terms in the present invention shall prevail.

Finally, it should be noted that in the context, relational terms such as first and second are only used to distinguish one entity or operation from another entity or operation, and do not necessarily require or imply that these entities or these operations have any such actual relationship or sequence between them. It should be understood that the terms used in this way are interchangeable under appropriate circumstances. This is merely a way of distinguishing objects with the same attributes in the description of the embodiments of the present invention. Furthermore, the terms “includes” and “comprises” include not only those elements but also other elements not expressly listed or elements inherent to such process, method, article or apparatus. Without further limitation, an element defined by the statement “including . . . ” does not exclude the presence of additional identical elements in a process, method, item, or device that includes the stated element. For a person having ordinary skill in the art, the specific meanings in the present invention of the terms in the present invention can be understood according to specific circumstances.

In the context, the term “chip” refers to any type of semiconductor chip or integrated circuit chip that realizes a specific function, and it also refers to any type of semiconductor die or integrated circuit die that realizes a specific function.

In the context, the term “flip chip” refers to any type of semiconductor chip or integrated circuit chip that realizes a specific function, as it also refers to any type of semiconductor die or integrated circuit die that realizes a specific function, which may be a single-layer chip and a vertically interconnected stacked chip.

In the context, the term “functional surface” refers to a surface of the chip that is provided with chip pin pads, while the term “non-functional surface” refers to an opposite surface relative to the functional surface.

In the context, the term “first direction” refers to a direction that is consistent with a stacking direction of the chip, and the term “second direction” refers to a direction that is opposite to the stacking direction of the chip. It should be understood that when the stacking direction of the chip changes, the directions referred to by “first direction” and “second direction” will also change accordingly. Therefore, “first direction” and “second direction” should not be limited to the specific directions shown in the drawings. The stacking direction of the chip refers to the direction in which the chips are stacked layer by layer, resulting in an increase in the height of the stacked chips. In the embodiments of the present invention, when discussing the relative relationship between chips positioned in different layers, the layer positioned in the relative relationship in the direction toward the first direction may be defined as the upper layer, while the layer positioned in the relative relationship in the direction away from the first direction may be defined as the lower layer.

In the context, the term “back-to-back” refers to the presence of some of the chips in the stacked chips, wherein the stacking thereof is realized by adhering their non-functional surfaces together.

The embodiments of the present invention aim to provide a back-to-back three-dimensional stacked fan-out packaging solution that ensures high chip interconnection density and integration, as well as high data transmission rates, while reducing packaging costs, improving packaging yield, simplifying the packaging process, and providing better heat dissipation and smaller packaging dimensions (especially making it thinner).

The following will first provide a detailed description of the solution provided by the embodiments of the present invention from the perspective of the manufacturing of the packaged device.

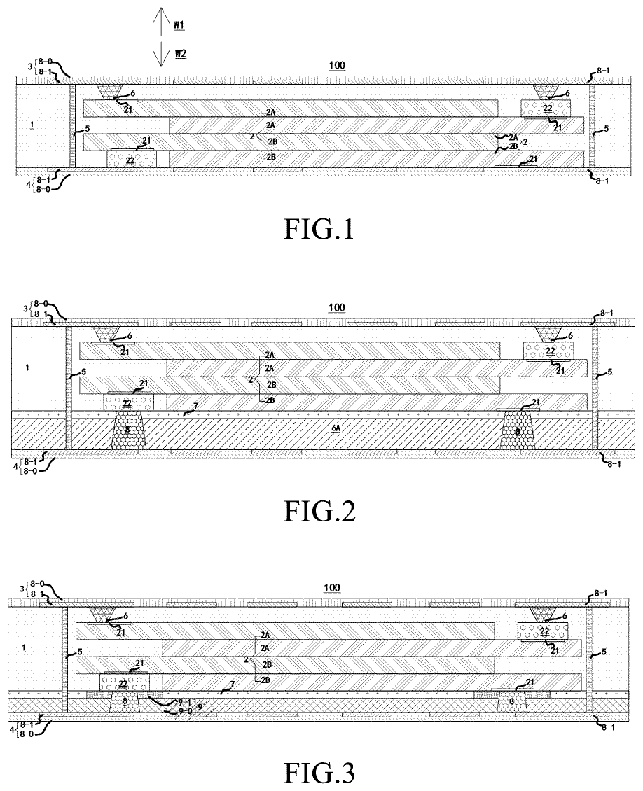

FIG. 1 schematically illustrates a vertical cross-sectional view of the back-to-back three-dimensional stacked fan-out packaging structure 100 according to an embodiment of the present invention. As shown in FIG. 1, the packaging structure 100 provided in this embodiment includes a packaging material layer 1, at least one set of stacked chips 2, a first redistribution layer 3 positioned on one side of the packaging material layer, and a second redistribution layer 4 positioned on the other side of the packaging material layer. Each set of stacked chips 2 includes at least one chip 2A with a functional surface facing a first direction W1 and at least one chip 2B with a functional surface facing a second direction W2. The packaging material layer 1 encapsulates the stacked chips 2. Preferably, the first direction and the second direction are opposite directions. The first redistribution layer 3 is positioned on the side of the packaging material layer facing the first direction, which is electrically connected to the chip with the functional surface facing the first direction, and the second redistribution layer 4 is positioned on the side of the packaging material layer facing the second direction, which is electrically connected to the chip with the functional surface facing the second direction.

Each chip of the stacked chip 2 has chip pin pads 21 on its functional surface. In a preferred embodiment, chip pin bumps 22 may be disposed on at least some of the chip pin pads 21 of at least some chips for electrical connection to the corresponding chips, particularly to realize electrical connection between the chips closest to the redistribution layers and the redistribution layers. As shown in FIG. 1, the stacked chips consist of four layers in total, with two layers of chips 2A facing the first direction W1 and two layers of chips 2B facing the second direction W2. Among the chips facing the first direction, one layer is closest to the first redistribution layer, and the other layer is farther away. Therefore, chip pin bumps 22 can be placed on some pin pads of the chips that are farther from the first redistribution layer, allowing that layer of chips to realize electrical connection with the first redistribution layer 3 through the chip pin bumps 22. Similarly, among the two layers of chips facing the second direction, one layer is closer to the second redistribution layer, and the other layer is farther away. Thus, chip pin bumps 22 can also be placed on some pin pads of the chips that are farther from the second redistribution layer, allowing that layer of chips to realize electrical connection with the second redistribution layer 4 through the chip pin bumps 22. It should be noted that in the embodiment of the present invention, the chips with the functional surface facing the first direction are stacked together using a stacking material, preferably the upper chip with the functional surface facing the first direction adhered to the functional surface of the lower chip with the functional surface facing the first direction through the stacking material, while exposing the chip pin bumps of the lower chip with the functional surface facing the first direction. Similarly, chips with the functional surface facing the second direction are also stacked together using a stacking material, specifically adhering the functional surface of the upper chip with the functional surface facing the second direction to the back of the lower chip with the functional surface facing the second direction, while exposing the chip pin bumps of the upper chip with the functional surface facing the second direction. Furthermore, the stacking material also adheres the chips with functional surfaces facing the first direction and the chips with functional surfaces facing the second direction back-to-back (i.e., non-functional surfaces adhered together), thereby achieving a back-to-back stacked packaging of multiple layers of chips.

As a possible implementation, as shown in FIG. 1, the packaging structure 100 also includes a vertical interconnect conductive structure 5 for electrically connecting the first redistribution layer 3 and the second redistribution layer 4, as well as a first conductive structure 6 disposed on the packaging material layer 1. The entire partial section of the vertical interconnect conductive structure 5 is fully set within the packaging material layer 1 and penetrates through the entire thickness of the packaging material layer. The first redistribution layer 3 and the second redistribution layer 4 both include redistribution insulating material 8-0 and redistribution conductive structures 8-1 formed on the redistribution insulating material 8-0. The chip pin pads 21 and chip pin bumps 22 of the chip with the functional surface facing the first direction are electrically connected to the redistribution conductive structure 8-1 of the first redistribution layer 3 through the first conductive structure 6 disposed on the packaging material layer, while the redistribution conductive structure 8-1 of the second redistribution layer 4 is directly electrically connected to the chip pin pads 21 and chip pin bumps 22 of the chip with the functional surface facing the second direction. Thus, the chips in the embodiments of the present invention can be arranged back-to-back, allowing for routing in both directions and achieving vertical electrical interconnection under back-to-back arrangements. This structure's packaging body does not require the preparation of through silicon vias on the chips, nor does it need to realize interconnection through leads and permanent carriers, resulting in higher data transmission rates and packaging yields, as well as lower packaging costs. In addition, due to the back-to-back packaging of some chips in this type of structure, interconnection wiring can be carried out in different directions. Compared to traditional packaging structures, under the condition that the number of chips in the packaging structure is the same, the interconnection wiring density in a single direction is effectively reduced (for instance, in the case of four chips, the traditional packaging structure requires interconnection wiring for all four chips in the same direction, while the back-to-back packaging in this application allows for fewer than four chips to be interconnected in the same direction). This significantly increases the available space for interconnection wiring, thereby further enhancing the number of chips that can be integrated within the packaging structure. Moreover, the packaging devices of this structure can interconnect chips in different directions separately, simplifying the interconnection process between chips with the functional surface facing the respective sides and their corresponding redistribution layers, making fabrication easier. It should be noted that the types, quantities, and functions of the chips in the embodiments of the present invention can be adjusted and configured according to the respective application scenarios and desired objectives. The functions of the chips can include storage capabilities, computational capabilities, etc. The functions of the chips within the same stacked chip can be the same or different, and similarly, the functions of the chips between different stacked chips can also be the same or different.

FIG. 2 schematically illustrates a vertical cross-sectional view of another embodiment of the back-to-back three-dimensional stacked fan-out packaging structure 100. The main difference from the embodiment shown in FIG. 1 is that, as shown in FIG.

2, the packaging structure 100 further includes a support structure 6A positioned between the packaging material layer 1 and the second redistribution layer 4. The stacked chips 2 are adhered to the support structure 6A through an adhesive material 7, and the second redistribution layer 4 is disposed on the surface of the support structure 6A that does not have adhered chips. In this embodiment, the vertical interconnect conductive structure 5 penetrates not only through the packaging material layer but also penetrates through the support structure 6A and the adhesive material 7 in the thickness direction. Furthermore, as shown in FIG. 2, in this embodiment, the packaging structure 100 also includes a second conductive structure 8 that penetrates through the support structure 6A and the adhesive material 7, enabling the chip 2B with the functional surface facing the second direction to realize electrical connection with the second redistribution layer 4 specifically through the second conductive structure 8 that penetrates through the support structure 6A and the adhesive material 7. The support structure 6A can be made from thermally conductive materials such as metals (copper, aluminum, etc.), ceramics (alumina, aluminum nitride, silicon carbide, etc.), composite materials (various double-sided copper-clad boards used in the printed circuit board industry, etc.), or a high temperature resistant protective film such as Teflon or PI coated with a high temperature resistant adhesive film. When using a high temperature resistant protective film, the thickness of the support structure can be set between 50-300 μm. The support structure in this embodiment is configured as a permanent carrier (i.e., it does not need to be removed during the packaging process) for the packaging structure, thus providing support and protection to the packaging structure, especially providing support and fixing for the chips, which helps improve the mechanical performance of the packaged device. When the support structure is made from a thermally conductive material, it enhances the thermal performance of the packaging structure, preventing poor thermal performance due to stacked chips, which could otherwise affect chip performance. It should be noted that in this embodiment, the adhesive material is not mandatory; the stacked chips can also be adhered directly to the support structure without adhesive material. For example, if the support structure is a high-temperature protective film, the stacked chips can be directly adhered to the high-temperature protective film. Thus, in other possible embodiments without adhesive material, the vertical interconnect conductive structure 5 can penetrate through both the support structure and the packaging material layer, and similarly, the second conductive structure 8 can penetrate through the support structure.

FIG. 3 schematically illustrates a vertical cross-sectional view of another embodiment of the back-to-back three-dimensional stacked fan-out packaging structure 100. The main difference from the embodiment shown in FIG. 1 is that, as shown in FIG. 3, in this embodiment, the packaging structure 100 also includes a fine interconnect layer 9 positioned between the packaging material layer 1 and the second redistribution layer 4, and a second conductive structure 8 that penetrates through the fine interconnect layer and the adhesive material. The stacked chips 2 are directly adhered to the fine interconnect layer 9 through the adhesive material 7. The second redistribution layer 4 covers one side, away from the stacked chips 2, of the fine interconnect layer 9. The chip 2B with the functional surface facing the second direction is electrically connected to the second redistribution layer 4 through the second conductive structure 8 that penetrates through the fine interconnect layer 9 and the adhesive material 7. The second redistribution layer 4 also needs to realize electrical connection with the fine interconnect layer 9 through the second conductive structure 8. In this embodiment, the second redistribution layer needs to be electrically connected to both the chip with the functional surface facing the second direction and the fine interconnect layer, thus allowing the chip with the functional surface facing the second direction to realize electrical interconnection through the second redistribution layer and the fine interconnect layer. Based on this, during the preparation process of the packaging structure, it is not necessary to realize direct electrical interconnection between the chip with the functional surface facing the second direction and the fine interconnect layer in advance, which can help reduce the difficulty of the process. As shown in FIG. 3, the fine interconnect layer 9 includes a fine interconnect insulating material 9-0 and a fine interconnect conductive structure 9-1. In this embodiment, the vertical interconnect conductive structure 5 not only penetrates through the packaging material layer 1 in the thickness direction but also penetrates through the adhesive material 7 and the fine interconnect insulating material 9-0 of the fine interconnect layer. As a possible implementation, when adhering the chips, the chip pin pads and chip pin bumps of the chip with the functional surface facing the second direction can be set to correspond precisely to the fine interconnect conductive structures of the fine interconnect layer. Subsequently, the second conductive structure can penetrate through the fine interconnect layer at the corresponding locations of the fine interconnect conductive structures to realize electrical connection between the second redistribution layer and the fine interconnect layer. The arrangement where the chip pin pads and chip pin bumps of the chip with the functional surface facing the second direction correspond to the fine interconnect conductive structures means that each chip pin pad 21 corresponds to a fine interconnect conductive structure, and each chip pin bump 22 corresponds to a fine interconnect conductive structure, allowing for a one-to-one correspondence. The second conductive structure can be set to penetrate through each fine interconnect conductive structure 9-1 and the adhesive material 7 at corresponding locations, enabling electrical connectivity between the chip with the functional surface facing the second direction and the second redistribution layer, as well as between the second redistribution layer and the fine interconnect layer (Although this embodiment is not illustrated in the figure, it can be understood from the schematic in FIG. 3. For instance, if the two fine interconnect conductive structures 9-1 in FIG. 3 are regarded as a single fine interconnect conductive structure 9-1, the resulting packaging structure effect from this embodiment is similar to that shown in FIG. 3). Specifically, the chip pin pad and chip pin bump of the chip with the functional surface facing the second direction correspond to the fine interconnect conductive structures in the fine interconnect layer, meaning that each chip pin pad or chip pin bump corresponds to two spaced fine interconnect conductive structures. In this case, each chip pin pad corresponds to two spaced fine interconnect conductive structures, and each chip pin bump also corresponds to two spaced fine interconnect conductive structures. The second conductive structure can specifically be set as the fine interconnect insulating material and the corresponding adhesive material between the two spaced fine interconnect conductive structures that correspond to the same chip pin pad or chip pin bump. This allows the chip with the functional surface facing the second direction to be electrical connected to the second redistribution layer and the second redistribution layer to be electrical connected to the fine interconnect line layer through the second conductive structure. FIG. 3 illustrates a specific structural example of the latter. As shown in FIG. 3, the adhesive material 7 directly bonds the functional surface of the chip with the functional surface facing the second direction, to the fine interconnect layer 9. The chip's chip pin pad 21 and chip pin bump 22 are aligned precisely with two spaced fine interconnect conductive structures 9-1 of the fine interconnect layer 9, meaning that a chip pin pad or a chip pin bump is positioned over two adjacent fine interconnect conductive structures 9-1 that are spaced apart. The second conductive structure 8 penetrates through the fine interconnect insulating material corresponding to the two spaced fine interconnect conductive structures 9-1 on which the chip pin pad or the chip pin bump is positioned, as well as the adhesive material at the corresponding positions, establishing electrical interconnection with both fine interconnect conductive structures 9-1. Thus, electrical communication can be realized between the chip with the functional surface facing the second direction, and the second redistribution layer, as well as between the second redistribution layer and the fine interconnect layer, through a middle fan-out approach. In other preferred embodiments, the fine interconnect conductive structure can be configured as an annular structure or an annular external pin pad (also referred to as an annular metal structure), specifically implemented such that the center consists of fine interconnect insulating material without metal, while the periphery has only a metal ring as the fine interconnect conductive structure. In this case, the chip with the functional surface facing the second direction is adhered such that each chip pin pad and chip pin bump correspond to an annular structure of the fine interconnect conductive structure, meaning that one chip pin pad corresponds to one annular structure of the fine interconnect conductive structure, and one chip pin bump corresponds to one annular structure of the fine interconnect conductive structure. The second conductive structure penetrates through the fine interconnect layer to the annular structure of the fine interconnect conductive structure corresponding to a chip pin pad or chip pin bump, passing through the fine interconnect insulating material in the middle of the annular structure and the adhesive material at the corresponding position, allowing for electrical communication between the chip with the functional surface facing the second direction, and the second redistribution layer, as well as between the second redistribution layer and the fine interconnect layer through the second conductive structure. Thus, electrical communication can also be realized between the chip and the second redistribution layer, as well as between the second redistribution layer and the fine interconnect layer through a middle fan-out approach. This packaging structure, formed by this method, includes a fine interconnect layer, enabling higher density electrical interconnections. Moreover, since it is a middle fan-out, the second conductive structure is placed on the fine interconnect insulating material, eliminating the need for openings in the fine interconnect conductive structure, such as the fine interconnect layer (creating openings in the fine interconnect conductive structure is very challenging due to its small and thin dimensions, leading to low product yields). This significantly reduces packaging difficulty and improves yield. Additionally, the chip in this packaging structure is adhered to the fine interconnect layer using adhesive material, ensuring that the chip's position is precisely fixed after the adhesive material cures, preventing positional shifts during encapsulation and reducing subsequent lithography process difficulties. Furthermore, the fine interconnect layer in this embodiment is pre-fabricated before encapsulation (as seen in the method section), allowing for multiple layers, thus providing more wiring layers compared to last fan-out configurations without inter-layer separation reliability issues. Additionally, pre-fabricated fine interconnect wiring can be made finer, as creating fine interconnect wiring on the surface of encapsulation material is quite difficult. Moreover, this packaging structure avoids the need to prepare flip chip bumps on the chip, as required in first fan-out configurations, which necessitate filling the bottom space of the flip chip with bottom fill or expensive MUF encapsulation material. Thus, the packaging process of this embodiment is simpler and more cost-effective.

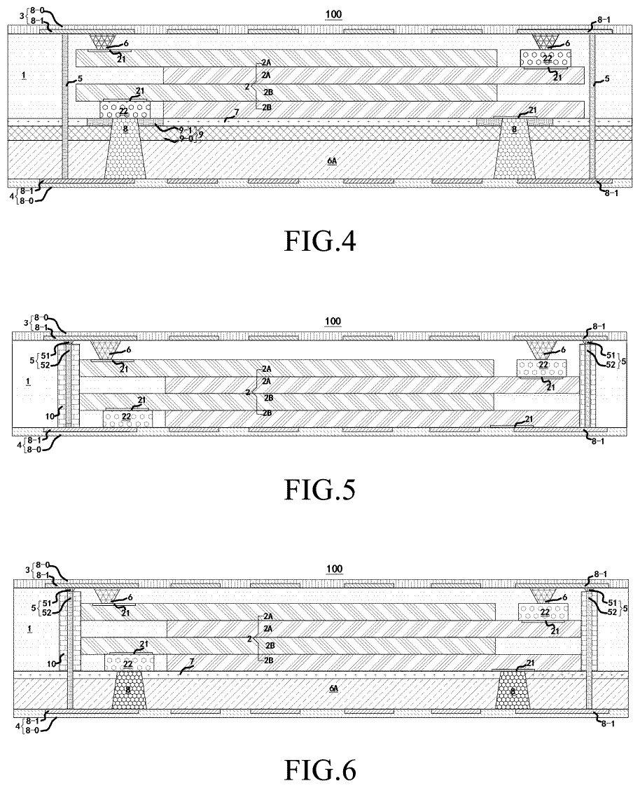

FIG. 4 schematically illustrates a vertical cross-sectional view of another embodiment of the back-to-back three-dimensional stacked fan-out packaging structure 100. The main difference from the embodiment shown in FIG. 3 is that, as shown in FIG. 4, in this embodiment, the packaging structure further includes a support structure 6A positioned between the fine interconnect layer 9 and the second redistribution layer 4, with the fine interconnect layer positioned on the support structure 6A. In this embodiment, the vertical interconnect conductive structure 5 penetrates not only through the packaging material layer 1, the adhesive material 7 and the fine interconnect insulating material 9-0 of the fine interconnect layer, but also through the support structure 6A. Accordingly, the second conductive structure 8 penetrates not only through the adhesive material 7 at the corresponding position and the fine interconnect insulating material 9-1 between the two spaced fine interconnect conductive structures 9-0 corresponding to the chip pin pads 21 or chip pin bumps 22 of the same chip of the fine interconnect layer 9, but also through the support structure 6A. The support structure 6A may be made of the same material as the support structure of the embodiment shown in FIG. 2.

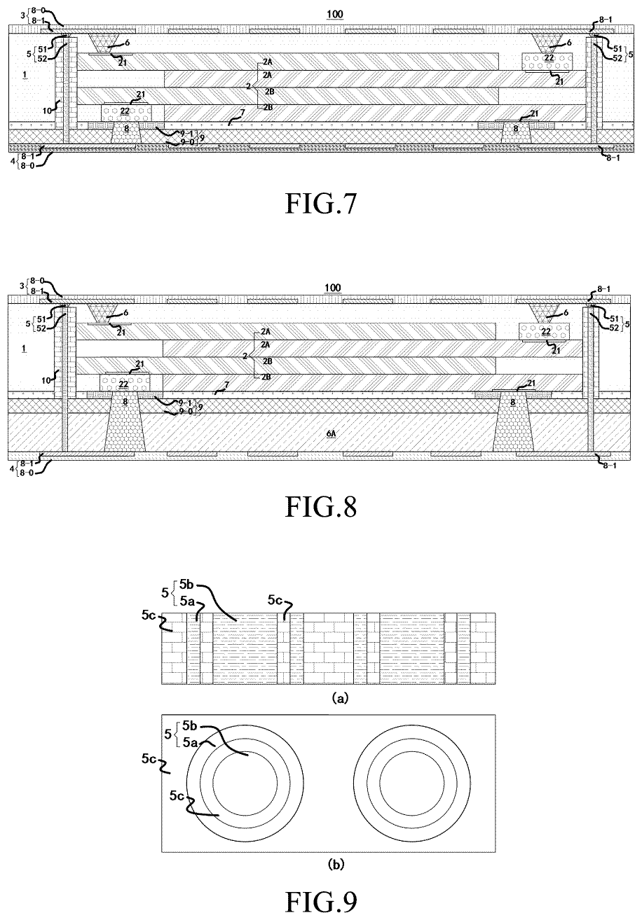

In other possible embodiments, a support insulating material may be pre-set above the area used for mounting chips, specifically designing the area for mounting chips as a recessed structure, thereby accurately defining the chip attachment region, facilitating rapid chip mounting and reducing the size of the packaged device. The height of the formed support insulating material is preferably not less than the height of the stacked chips, and the support insulating material is encapsulated by a packaging material layer. In such a case, the vertical interconnect conductive structure may also be configured such that a portion of the segments is positioned in the packaging material layer, while another portion is situated in the support insulating material. FIGS. 5 to 8 schematically illustrate such a back-to-back three-dimensional stacked fan-out packaging structure, wherein the structure in FIG. 5 corresponds to that in FIG. 1, with the only difference being that the packaging structure includes a support insulating material 10 used to define the recessed chip attachment region, and the vertical interconnect conductive structure 5 includes a first vertical conductive structure 52 positioned within the support insulating material 10 and a second vertical conductive structure 51 situated in the packaging material layer 1. The first vertical conductive structure 52 and the second vertical conductive structure 51 together form the vertical interconnect conductive structure 5 that is electrically connected the first redistribution layer and the second redistribution layer. Accordingly, FIG. 6 corresponds to FIG. 2, FIG. 7 corresponds to FIG. 3, and FIG. 8 corresponds to FIG. 4, with the only difference being the manner of setting the vertical interconnect conductive structure, which is conceptually similar to the difference between FIG. 5 and FIG. 1. The vertical interconnect conductive structures in FIGS. 6 to 8 are similar to the implementation in FIG. 5, with the distinction being that the layers penetrated by the vertical interconnect conductive structure in the thickness direction are different. For example, in FIG. 6, the vertical interconnect conductive structure additionally needs to penetrate the adhesive material 7 and the support structure 6A (wherein the segment that penetrates the adhesive material 7 and the support structure 6A may be referred to as a third vertical conductive structure). In FIG. 7, the vertical interconnect conductive structure additionally needs to penetrate the fine interconnect layer 9′s fine interconnect insulating material 9-0 (wherein the segment that penetrates the fine interconnect insulating material 9-0 may be referred to as a third vertical conductive structure). In FIG. 8, the vertical interconnect conductive structure additionally needs to penetrate both the fine interconnect layer 9's fine interconnect insulating material 9-0 and the support structure 6A (wherein the segment that penetrates both the fine interconnect insulating material 9-0 and the support structure 6A may be referred to as a third vertical conductive structure). These can be visually and clearly understood in conjunction with the previous descriptions, thus no further elaboration is necessary. It should be noted that in the embodiments shown in FIGS. 5 to 8, the number of vertical interconnect conductive structures may be set to be greater than that in the embodiments shown in FIGS. 1 to 4, and the density of vertical interconnect conductive structures may be set to be higher than that in the embodiments shown in FIGS. 1 to 4. The reason is that in the embodiments shown in FIGS. 1 to 4, the vertical interconnect conductive structures are set within the packaging material, resulting in a deeper depth that complicates the filling of a conductive material, thereby limiting the ratio of depth to diameter of the vertical interconnect conductive structures and consequently restricting their quantity and density. Thus, in the embodiments shown in FIGS. 1 to 4, the density of vertical interconnect conductive structures cannot be very high, which may affect the interconnection density of the packaged device to some extent. However, in the embodiments shown in FIGS. 5 to 8, the vertical interconnect conductive structures are divided into a first vertical conductive structure 52 positioned within the support insulating material 10 and a second vertical conductive structure 51 positioned within the packaging material layer, allowing for the pre-fabrication of the first vertical conductive structure prior to encapsulation, thus enabling the creation of vertical interconnect conductive structures with smaller apertures and higher densities, thereby achieving an increase in the interconnection density of the packaged device.

As a preferred embodiment, the second vertical conductive structure positioned within the packaging material layer is coaxially electrically connected to the corresponding first vertical conductive structure, and in embodiments that include a third vertical conductive structure, the second vertical conductive structure is also coaxially electrically connected to the corresponding third vertical conductive structure, thereby shortening the transmission distance of the vertical conductive structures and improving their transmission efficiency.

In some preferred embodiments, the vertical interconnect conductive structure 5 may be configured to include an outer loop line 5a used as a ground line or signal shielding line and a vertical conductive line 5b positioned within the outer loop line 5a used as a conductive line. FIG. 9 illustrates a cross-sectional view of such a structure of the vertical interconnect conductive structure 5. As shown in FIG. 9, the center of each individual vertical interconnect conductive structure 5 is formed by a solid conductive material (such as copper) creating the vertical conductive line 5b, surrounded by filled insulating material 5c, with an outer loop line 5a formed by conductive material surrounding the insulating material 5c. This structure of the vertical interconnect conductive structure can simultaneously realize grounding and electrical interconnection functions through a single vertical interconnect structure, unlike traditional vertical interconnect conductive structures formed solely from a solid conductive material that require two vertical interconnect structures to work together as a pair to realize grounding and electrical interconnection functions. This greatly saves the packaging space occupied by vertical interconnect structures and increases the packaging density. Furthermore, since this vertical interconnect conductive structure simultaneously includes conductive and insulating material, it possesses high mechanical strength, low stress, and high reliability.

As a possible embodiment, the material used for the chip mounting is preferably a thermally conductive material such as metal alloy solder, silver paste, or nano-silver paste, to further enhance the heat dissipation effect of the packaged device. The adhesive material may use the same material as the mounting material. It should be noted that in the present invention embodiment, the adhesive material needs to cover the surface of the fine interconnect layer or the support structure, and when it is covering the surface of the fine interconnect layer, the adhesive material is preferably an insulating adhesive material.

As a preferred embodiment, the chip pin bumps set on at least a portion of the chip pin pads of at least a portion of the chips have different heights, thereby ensuring that the end surfaces of the free ends of the pin bumps of the chips facing the same direction within the stacked chips are positioned in the same plane, facilitating electrical connection between the chips and the redistribution layer's redistribution conductive structure. More preferably, chips without chip pin bumps can also be mounted at the corresponding orientations on the ends of the stacked chips, for example, in the chip group facing the first direction, the chip without chip pin bumps is positioned closest to the first redistribution layer, while in the chip group facing the second direction, the chip without chip pin bumps is positioned closest to the second redistribution layer. At the same time, the heights of the pin bumps of other chips are designed such that when all chips are mounted, the end surfaces of the free ends of the pin bumps of the chips with functional surfaces facing the same direction are flush with the functional surface of the closest chip to the corresponding redistribution layer (i.e., flush with the functional surface of the chip at the end closest to the functional surface in the same direction). This arrangement allows the pin heights of the chips with functional surfaces facing the same direction to be consistent (i.e., positioned in the same plane), enabling direct wiring on the chip pin pads and pin bumps, or ensuring that the depth and dimensions of the openings prepared in the packaging material layer for the first conductive structure and the second conductive structure are consistent, thereby making all opening process parameters and the processes for filling conductive material consistent, simplifying the process, making the process easier to control, and reducing process costs.

It should be noted that the structures shown above are merely some embodiments of the packaging structure of the present invention. It is not difficult for those skilled in the art to understand that some features of the above packaging structures can be freely combined, such as the number of layers of stacked chips can be two, three, or more layers, the number of chips with functional surfaces facing the first direction can be one layer or more layers, the number of chips with functional surfaces facing the second direction can also be one layer or more layers, the number of sets of stacked chips can be two groups or more groups, the functions of the mounted chips can be the same or completely different, the packaging structure may include a support structure or may not include a support structure, the packaging structure may include a fine interconnect layer or may not include a fine interconnect layer, and the vertical interconnect conductive structure can be designed as a segmented design (such as including a first vertical conductive structure and a second vertical conductive structure) or as a monolithic design, etc. Through these free combinations and transformations, it is evident that more embodiments of the packaging structure can be obtained, and these variations of the packaging structures should be regarded as falling within the protection scope of the present invention.

In practical applications, packaging external connection pin pads and solder balls can be set on the first redistribution layer or the second redistribution layer of the packaging structure described above, allowing the chips within the packaging structure to realize electrical connectivity with the outside, thus forming a desired packaged device or packaging module. Since the packaging structure can perform wiring in both vertical directions and realize non-TSV stacked vertical interconnections between chips, the available space in the XY plane of the packaging structure is larger, allowing for the integration of more sets of stacked chips. Based on this, as a preferred invention method, the back-to-back three-dimensional stacked fan-out packaging structure described above can also be directly used as a packaging carrier board, and further chip flip-chip bonding can be performed on the packaging carrier board, allowing the stacked chips in the packaging structure to electrically connect with the flip-chip adhered chips, thus forming a packaging module with richer functions, higher performance, and smaller packaging size. The following will explain this preferred application scenario in conjunction with the accompanying drawings.

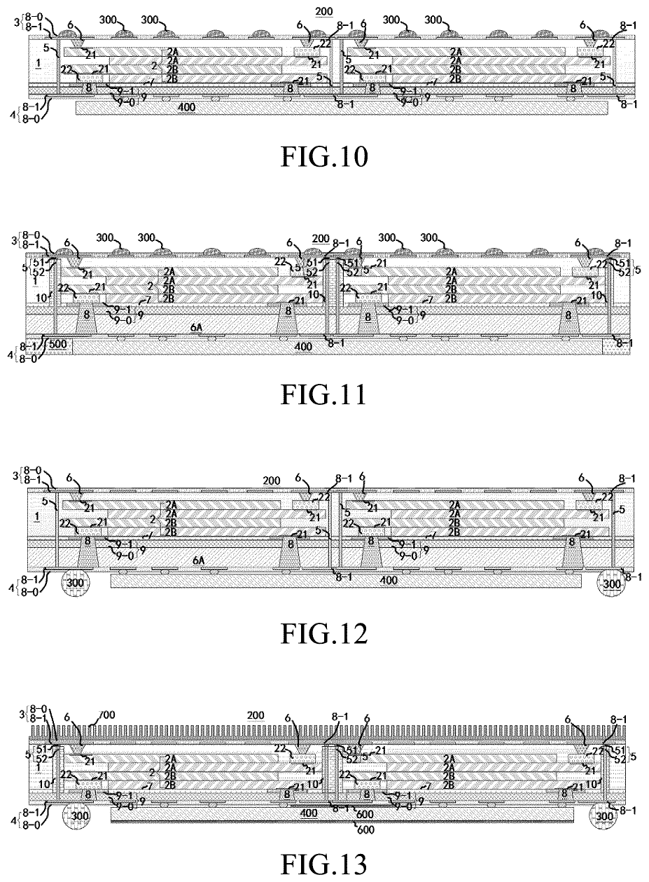

FIG. 10 illustrates a vertical cross-sectional view of a back-to-back three-dimensional stacked fan-out packaging module according to one embodiment. As shown in FIG. 10, in this application scenario, the packaging module includes a back-to-back three-dimensional stacked fan-out packaging structure based on the configuration described in the embodiment of FIG. 3, except that this packaging structure includes two sets of stacked chips 2. In this case, the packaging structure exists as a packaging carrier board 200, and thus, packaging external connection pin pads are set on at least a portion of the redistribution conductive structures 8-1 of the first redistribution layer and the second redistribution layer, wherein solder balls 300 are set on the packaging external connection pin pads of the first redistribution layer 3, and a flip chip 400 is set on the packaging external connection pin pads of the second redistribution layer 4. In this scenario, the flip chip 400 is prepared with pin bumps of high interconnection density, with the interconnection density of these pin bumps being C4 or higher, and their pitch being less than that of the solder balls 300. This further enhances the interconnection density of the packaged device and the integration of the chips, and the resulting higher density packaging module can be adapted to different application scenarios through adjustments in the functional types of the stacked chips and the flip chip.

FIG. 11 illustrates a vertical cross-sectional view of another embodiment of a back-to-back three-dimensional stacked fan-out packaging module. As shown in FIG. 11, in this application scenario, the packaging carrier board in the packaging module is formed based on the construction described in the embodiment of FIG. 8, except that this packaging structure includes two sets of stacked chips. The arrangement of the flip chip 400 and the solder balls 300 is the same as in FIG. 10. Additionally, as shown in FIG. 11, the packaging module of this embodiment also lays out a heat dissipation enhancement structure 500 around the flip chip 400 to provide both heat dissipation and support for the flip chip 400, enhancing the mechanical stability and heat dissipation performance of the packaging module. In this embodiment, the vertical interconnect conductive structure 5 not only provides electrical interconnection between the first redistribution layer and the second redistribution layer but can also serve as a heat dissipation ring around the flip chip 400 (i.e., conducting heat generated by the stacked chips to the other side of the vertical interconnect conductive structure to utilize the heat dissipation enhancement structure of the flip chip to dissipate heat from the stacked chips), further providing heat dissipation for the packaging module.

FIG. 12 illustrates a vertical cross-sectional view of yet another embodiment of a back-to-back three-dimensional stacked fan-out packaging module. As shown in FIG. 12, in this application scenario, the packaging carrier board 200 in the packaging module is formed based on the construction described in the embodiment of FIG. 4, except that this packaging structure includes two sets of stacked chips. In this embodiment, the flip chip 400 is positioned on the second redistribution layer 4, but unlike the previous real-time method, the solder balls 300 are set on the same side as the flip chip 400, i.e., also set on the second redistribution layer. This allows the space on the other side of the redistribution layer to be reserved for the installation of heat dissipation structures.

FIG. 13 illustrates a vertical cross-sectional view of yet another embodiment of a back-to-back three-dimensional stacked fan-out packaging module. As shown in FIG. 13, in this application scenario, the packaging carrier board 200 in the packaging module is formed based on the construction described in the embodiment of FIG. 7, except that this packaging structure includes two sets of stacked chips 2. In this embodiment, the arrangement of the flip chip 400 and the solder balls 300 is the same as in FIG. 12. Preferably, in this embodiment, a microchannel heat dissipation structure 600 is also set on the flip chip 400, and a heat dissipation device 700 is set on the first redistribution layer, thereby further enhancing the heat dissipation effect of the packaging module, ensuring better device performance and longer device lifespan. Exemplarily, the heat dissipation device 700 may be a liquid cooling device, such as a water cooling device.

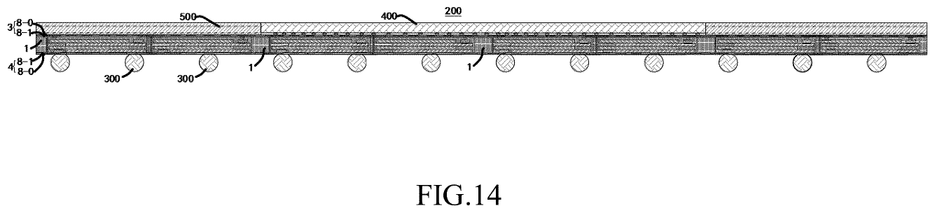

FIG. 14 illustrates a vertical cross-sectional view of yet another embodiment of a back-to-back three-dimensional stacked fan-out packaging module. As shown in FIG. 14, in this application scenario, the packaging carrier board 200 in the packaging module is formed based on the construction described in the embodiment of FIG. 1, except that this packaging structure includes eight sets of stacked chips 2. In this embodiment, the flip chip 400 is positioned on the first redistribution layer 3, and the solder balls 300 are positioned on the second redistribution layer 4, with a heat dissipation enhancement structure 500 laid out around the flip chip 400.

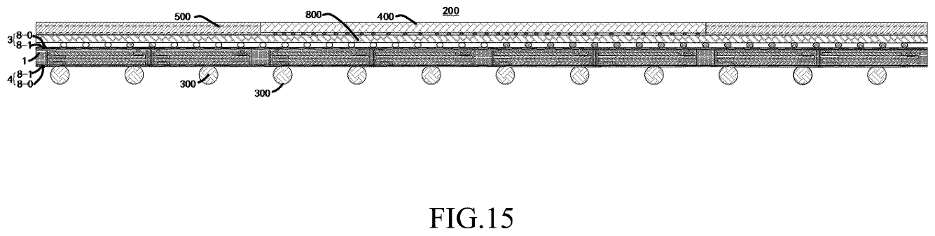

FIG. 15 illustrates a vertical cross-sectional view of yet another embodiment of a back-to-back three-dimensional stacked fan-out packaging module. As shown in FIG. 15, differing from the embodiment shown in FIG. 14, the flip chip 400 of the this embodiment is arranged on the packaging carrier board 200 via a fine line adapter board 800. That is, as illustrated in FIG. 15, the packaging module of this embodiment further includes the fine line adapter board 800 disposed on the first redistribution layer 3 of the packaging carrier board 200 (which may also be disposed on a second redistribution layer in other embodiments). The fine line adapter board 800 is electrically connected to the first redistribution layer through pin bumps of high interconnection density (C4 or higher), and the flip chip 400 is mounted on the fine line adapter board 800 and is electrically connected to it. Thus, the flip chip 400 is electrically connected to the first redistribution layer through the fine line adapter board 800, achieving interconnection with the stacked chips. This embodiment of the packaging module not only has higher mechanical strength but also allows for precise routing on the fine line adapter board 800 as needed. Since the fine line adapter board can realize higher pin density and more pin numbers, it can further enhance the interconnection density and integration of the packaging module. Additionally, the fine line adapter board is flatter, making it easier for flip-chip mounting and reducing the process difficulty of packaging the flip chip.

It should be noted that the structures shown above are merely some embodiments of the packaging module of the present invention. It is not difficult for those skilled in the art to understand that the above packaging module can also be realized based on any other packaging structure of the aforementioned embodiments, not limited to forming the packaging carrier board based on a selected specific embodiment's packaging structure. Moreover, the features of the packaging module described in the above embodiments can be freely combined, such as the number of sets of stacked chips, the positions of the stacked chips, whether to set the heat dissipation enhancement structure, whether to set the heat dissipation device, whether to set the microchannel heat dissipation structure, the positions of the solder balls, and the positions of the fine line adapter board, etc., can all be freely combined and transformed according to needs. Through these free combinations and transformations, it is evident that more embodiments of the packaging module can be obtained, and these variations of the packaging modules should be regarded as falling within the protection scope of the present invention.

Additionally, it should be noted that the stacked chips and flip chips in the embodiments of the present invention can be selected as any functional chips that meet the desired requirements. The stacked chips and flip chips can be chips of the same function or chips of different functions. Exemplarily, the stacked chips may be memory chips, while the flip chips may be CPUs or GPUs.

A detailed description of the preparation method for the back-to-back three-dimensional stacked fan-out packaging structure described above will be provided below in conjunction with the accompanying drawings.

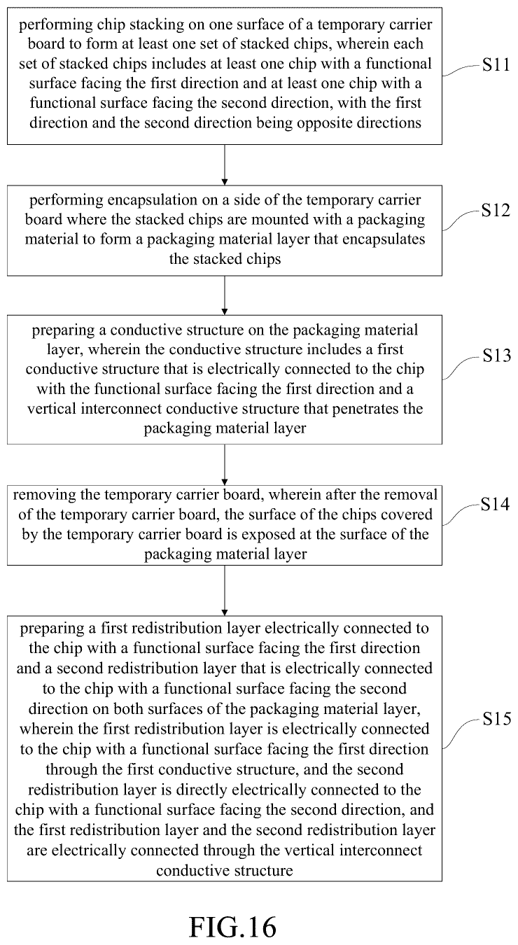

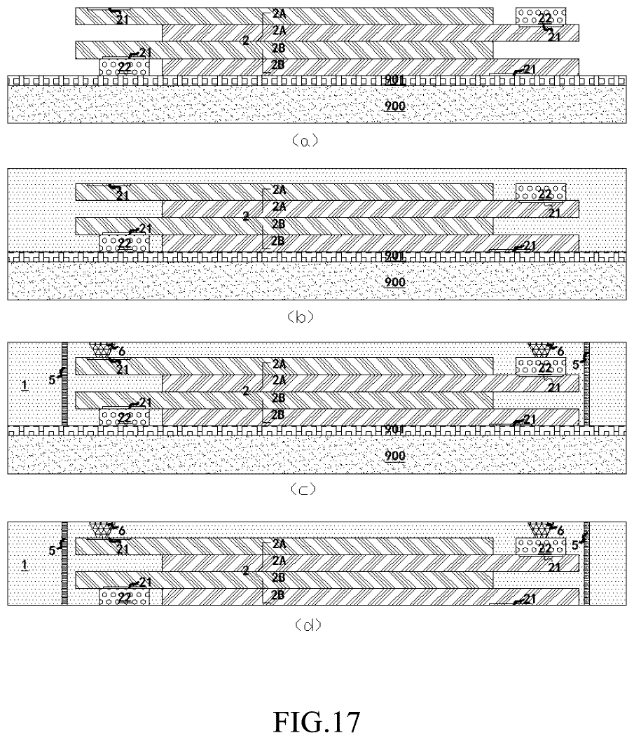

FIGS. 16 and 17 schematically illustrate a preparation method for the packaging structure shown in FIG. 1. As shown in FIGS. 16 and 17, the preparation method includes:

Operation S11: performing chip stacking on one surface of a temporary carrier board to form at least one set of stacked chips, wherein each set of stacked chips includes at least one chip with a functional surface facing the first direction and at least one chip with a functional surface facing the second direction, with the first direction and the second direction being opposite directions. In this operation, different chips are stacked and adhered together through a stacking material, with chips facing different directions adhered back-to-back (i.e., non-functional surfaces in contact). The chip closest to the temporary carrier board is adhered to the temporary carrier board through a removable material (of course, in some embodiments, the lowest layer chip can also be adhered to the removable material through adhesive material). Preferably, the chips are mounted such that the pin bumps of the other chips mounted prior to this chip are exposed, meaning that regardless of the chip orientation, at least some of the chip pin bumps or chip pin pads are not covered by other stacked chips, facilitating electrical connections between the layers of chips. It should be noted that if the positions of the chip pin pads cause the pin bumps of the chips in the middle layers to be easily covered during stacking, the positions of the chip pin pads on the corresponding chips can be adjusted during the preparation of the chip pin bumps through redistribution processes to ensure that the pin bumps of the chips in the middle layers remain exposed after mounting. The stacked chips can include two layers or more. Taking a set of stacked chips that includes two layers facing the first direction and two layers facing the second direction as an example, the intermediate structure of the packaging structure obtained through this step is shown in FIG. 17 (a), where the stacked chips are adhered to the temporary carrier board 900 through the removable material 901. Among them, the lower layer chip facing the first direction is prepared with chip pin bumps 22, while the uppermost chip is not prepared with chip pin bumps, and the lower layer chip facing the second direction is not prepared with chip pin bumps, while the chip above the lower layer chip facing the second direction is prepared with chip pin bumps. Exemplarily, the stacking material may be a thermally conductive adhesive such as metal alloy solder, silver paste, or nano-silver paste.

Operation S12: performing encapsulation on a side of the temporary carrier board where the stacked chips are mounted with a packaging material to form a packaging material layer that encapsulates the stacked chips. The intermediate structure of the packaging structure obtained through this step is shown in FIG. 17 (b), where the side of the stacked chips away from the temporary carrier board is completely encapsulated by the packaging material.

Operation S13: preparing a conductive structure on the packaging material layer, wherein the conductive structure includes a first conductive structure that is electrically connected to the chip with the functional surface facing the first direction and a vertical interconnect conductive structure that penetrates the packaging material layer. In this operation, through-holes and blind holes can be prepared on the packaging material layer. The positions of the blind holes can correspond to the respective chip pin bumps and chip pin pads of the chips with functional surfaces facing the first direction. Subsequently, a conductive material can be filled into the through-holes to form the vertical interconnect conductive structure and filled into the blind holes to form the first conductive structure. The through-holes in the packaging material layer can be prepared using methods such as laser drilling, photolithography, or dry etching, while blind holes corresponding to the pin bumps and/or pin pads of the chips can be prepared using methods such as laser drilling, photolithography, dry etching, or grinding. The intermediate structure of the packaging structure obtained through this step is shown in FIG. 17 (c).

Operation S14: removing the temporary carrier board, wherein after the removal of the temporary carrier board, the surface of the chips covered by the temporary carrier board is exposed at the surface of the packaging material layer. Depending on the material characteristics of the removable material on the temporary carrier board, the temporary carrier board can be removed using suitable methods such as heating, chemical methods, laser removal, UV light removal, heating and mechanical force removal, etc. The effect cross-sectional view of the intermediate structure obtained after removing the temporary carrier board is shown in FIG. 17 (d), where the surfaces of the chips covered by the temporary carrier board 900 and the chip pin bumps 22 of the chips with functional surfaces facing the second direction are flush and exposed at the surface of the packaging material layer 1, with the vertical interconnect conductive structure 5 penetrating through the packaging material layer 1.

Operation S15: preparing a first redistribution layer electrically connected to the chip facing the first direction and a second redistribution layer that is electrically connected to the chip facing the second direction on both surfaces of the packaging material layer, wherein the first redistribution layer is electrically connected to the chip facing the first direction through the first conductive structure, and the second redistribution layer is directly electrically connected to the chip facing the second direction, and the first redistribution layer and the second redistribution layer are electrically connected through the vertical interconnect conductive structure. Through this step, the packaging structure as shown in FIG. 1 can be prepared.

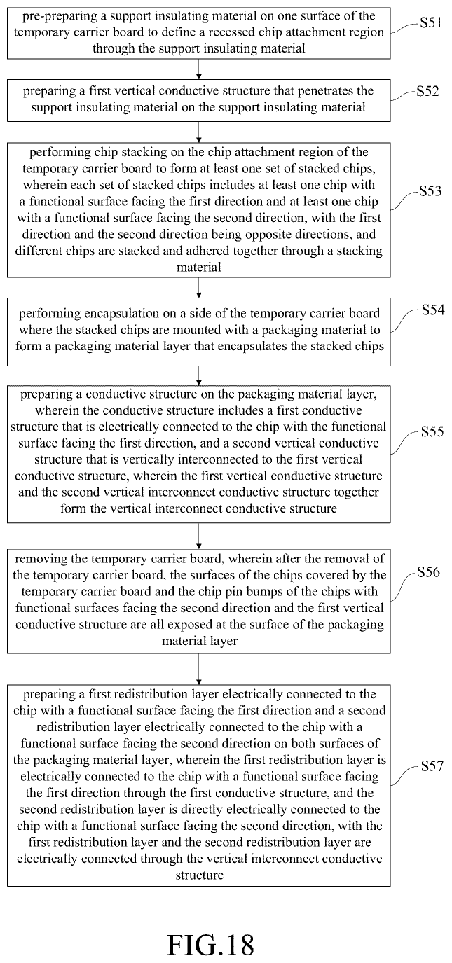

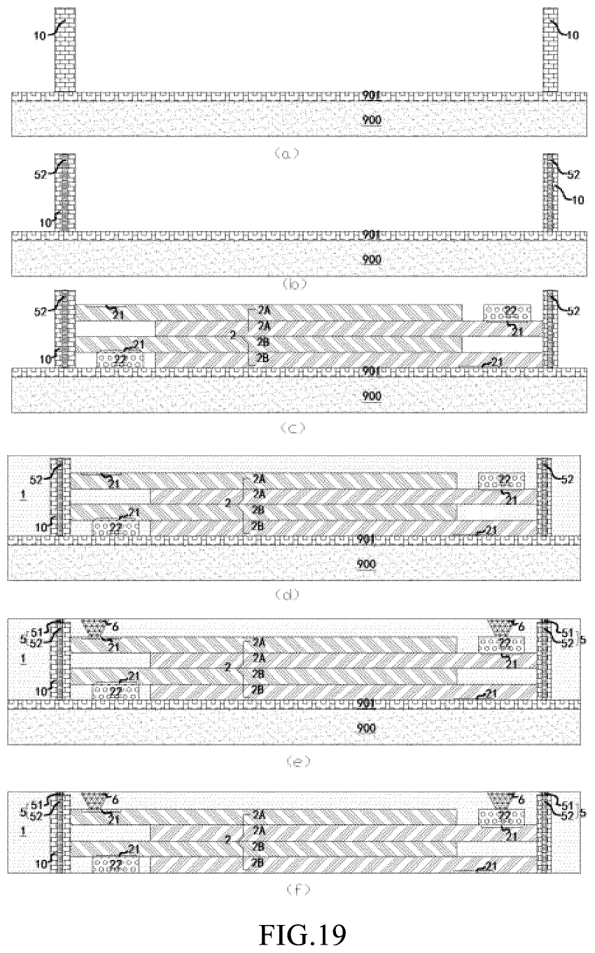

FIGS. 18 and 19 schematically illustrate a preparation method for the packaging structure shown in FIG. 5. Compared to the method shown in FIGS. 16 and 17, the main difference lies in the different vertical interconnect packaging structure. As shown in FIGS. 18 and 19, the preparation method includes:

Operation S51: pre-preparing a support insulating material on one surface of the temporary carrier board to define a recessed chip attachment region through the support insulating material. The intermediate structure of the packaging structure obtained through this step is shown in FIG. 19 (a), including the support insulating material 10 protruding from the temporary carrier board 900 and the recessed portion defined as the chip attachment region (i.e., the area positioned between the two support insulating materials 10), wherein the temporary carrier board 900 includes a removable material 901.

Operation S52: preparing a first vertical conductive structure that penetrates the support insulating material on the support insulating material. The intermediate structure of the packaging structure obtained through this step is shown in FIG. 19 (b), wherein the preparation process of the first vertical conductive structure 52 refers to the process of preparing the vertical interconnect conductive structure described in FIG. 16.

Operation S53: performing chip stacking on the chip attachment region of the temporary carrier board to form at least one set of stacked chips, wherein each set of stacked chips includes at least one chip with a functional surface facing the first direction and at least one chip with a functional surface facing the second direction, with the first direction and the second direction being opposite directions, and different chips are stacked and adhered together through a stacking material. The intermediate structure of the packaging structure obtained through this step is shown in FIG. 19 (c), wherein the relevant description of chip mounting refers to the content described in FIG. 16.

Operation S54: performing encapsulation on a side of the temporary carrier board where the stacked chips are mounted with a packaging material to form a packaging material layer that encapsulates the stacked chips. The intermediate structure of the packaging structure obtained through this step is shown in FIG. 19 (d), where the packaging material layer 1 completely encapsulates the stacked chips 2, the support insulating material 10, and the side of the first vertical conductive structure 52 away from the temporary carrier board 900.

Operation S55: preparing a conductive structure on the packaging material layer, wherein the conductive structure includes a first conductive structure that is electrically connected to the chip with the functional surface facing the first direction, and a second vertical conductive structure that is vertically interconnected to the first vertical conductive structure, wherein the first vertical conductive structure and the second vertical interconnect conductive structure together form the vertical interconnect conductive structure. The intermediate structure of the packaging structure obtained through this step is shown in FIG. 19 (e). The preparation of the first conductive structure 6 can refer to the relevant description in FIG. 16. The difference from FIG. 16 is that in this method, the packaging material layer 1 completely encapsulates the support insulating material 10 and the surface of the first vertical conductive structure 52 away from the temporary carrier board, thus in this embodiment, a second vertical conductive structure 51 is also prepared at the position corresponding to the first vertical conductive structure 52 in the packaging material layer 1. The preparation of the second vertical conductive structure can also be realized by first drilling holes and then filling a conductive material.

Operation S56: removing the temporary carrier board, wherein after the removal of the temporary carrier board, the surfaces of the chips covered by the temporary carrier board and the chip pin bumps of the chips with functional surfaces facing the second direction and the first vertical conductive structure are all exposed at the surface of the packaging material layer. The intermediate structure of the packaging structure obtained through this step is shown in FIG. 19 (f).

Operation S57: preparing a first redistribution layer electrically connected to the chip with a functional surface facing the first direction and a second redistribution layer electrically connected to the chip with a functional surface facing the second direction on both surfaces of the packaging material layer, wherein the first redistribution layer is electrically connected to the chip with a functional surface facing the first direction through the first conductive structure, and the second redistribution layer is directly electrically connected to the chip with a functional surface facing the second direction, with the first redistribution layer and the second redistribution layer are electrically connected through the vertical interconnect conductive structure. Through this step, the packaging structure as shown in FIG. 5 can be prepared.

Of course, in other possible embodiments, the specific preparation processes of the support insulating material in operation S51 and the first vertical conductive structure in operation S52 can also be realized by first covering the support insulating material on the temporary carrier board, then photolithographically processing the covered support insulating material according to the desired positions and quantities of the first vertical conductive structure to form corresponding through-hole structures at the desired positions, followed by electroplating the through-hole structures to form the first vertical conductive structure, and finally removing the excess support insulating material to prepare the structure effect shown in FIG. 19 (b).

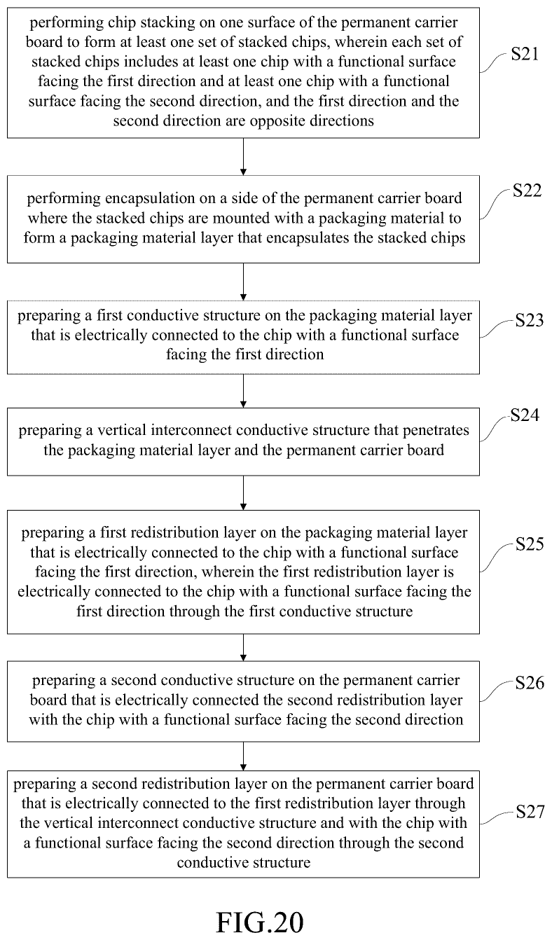

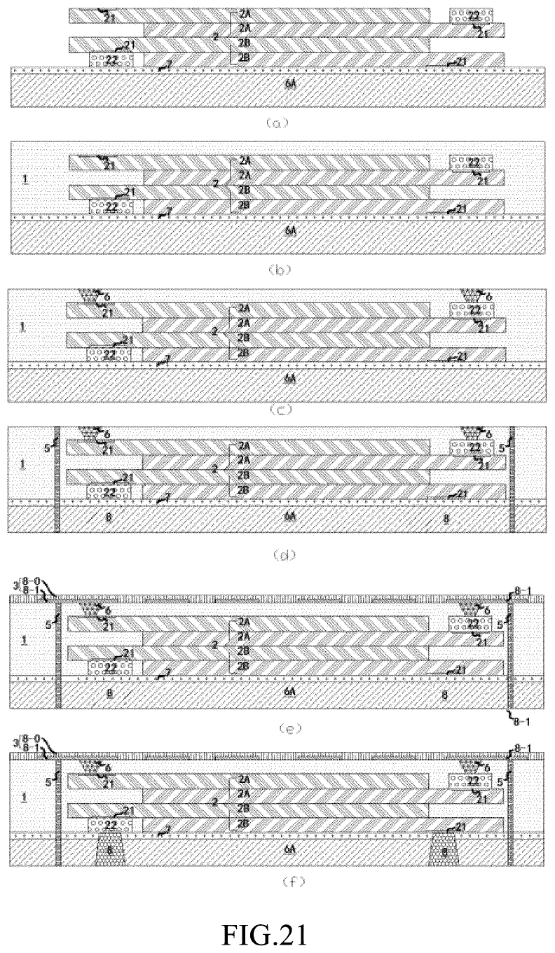

FIGS. 20 and 21 schematically illustrate a preparation method for the packaging

structure shown in FIG. 2. Compared to the method shown in FIG. 16, the main difference lies in the use of a permanent carrier board as the support structure, thus there is no step of removing the carrier board. Therefore, the specific details of the steps that are the same as those in FIG. 16 will not be repeated, and only the steps with differences will be explained. Specifically, as shown in FIGS. 20 and 21, the preparation method includes:

Operation S21: performing chip stacking on one surface of the permanent carrier board to form at least one set of stacked chips, wherein each set of stacked chips includes at least one chip with a functional surface facing the first direction and at least one chip with a functional surface facing the second direction, and the first direction and the second direction are opposite directions. The different chips are stacked and adhered together through a stacking material. The intermediate structure of the packaging structure obtained through this step is shown in FIG. 21 (a), where the stacked chips are set on the permanent carrier board through adhesive material 7, with the permanent carrier board serving as the support structure 6A.

Operation S22: performing encapsulation on a side of the permanent carrier board where the stacked chips are mounted with a packaging material to form a packaging material layer that encapsulates the stacked chips. The intermediate structure of the packaging structure obtained through this step is shown in FIG. 21 (b).

Operation S23: preparing a first conductive structure on the packaging material layer that is electrically connected to the chip with a functional surface facing the first direction. The intermediate structure of the packaging structure obtained through this step is shown in FIG. 21 (c).

Operation S24: preparing a vertical interconnect conductive structure that penetrates the packaging material layer and the permanent carrier board on the packaging material layer and the permanent carrier board. In contrast to the method in FIG. 16, in this method, the vertical interconnect conductive structure needs to penetrate not only the packaging material layer but also the adhesive material and the permanent carrier board. The intermediate structure of the packaging structure obtained through this step is shown in FIG. 21 (d).

Operation S25: preparing a first redistribution layer on the packaging material layer that is electrically connected to the chip with a functional surface facing the first direction, wherein the first redistribution layer is electrically connected to the chip with a functional surface facing the first direction through the first conductive structure. The intermediate structure of the packaging structure obtained through this step is shown in FIG. 21 (e).

Operation S26: preparing a second conductive structure on the permanent carrier board that is electrically connected the second redistribution layer with the chip with a functional surface facing the second direction. In this method, since the permanent carrier board exists as a support structure within the packaging structure, to ensure that the second redistribution layer is electrically connected to the chip with a functional surface facing the second direction, a second conductive structure that is electrically connected to the chip with a functional surface facing the second direction needs to be prepared on the permanent carrier board. Specifically, blind holes can be made at positions on the permanent carrier board corresponding to the respective chip pin bumps and chip pin pads, wherein the blind holes penetrate through the permanent carrier board and the adhesive material, connecting with the respective chip pin bumps and chip pin pads. Subsequently, a conductive material can be filled into the blind holes to form the second conductive structure. The intermediate structure of the packaging structure obtained through this step is shown in FIG. 21 (f).

Operation S27: preparing a second redistribution layer on the permanent carrier board that is electrically connected to the first redistribution layer through the vertical interconnect conductive structure and with the chip with a functional surface facing the second direction through the second conductive structure. Through this step, the packaging structure as shown in FIG. 2 can be prepared. In this step, unlike the method shown in FIG. 16, the second redistribution layer is prepared on the permanent carrier board, with some positions of the redistribution conductive structure corresponding to the vertical interconnect conductive structure and some positions corresponding to the second conductive structure.

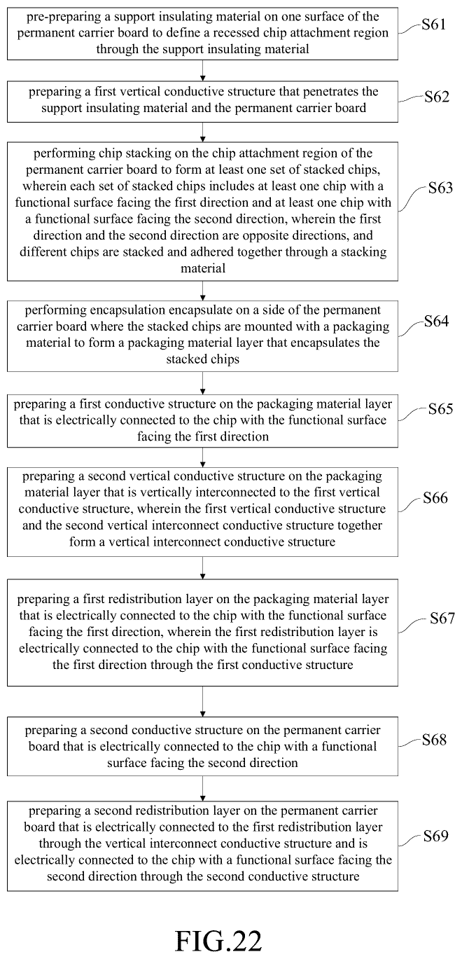

FIG. 22 schematically illustrates the preparation method for the packaging structure shown in FIG. 6. The main difference from the method shown in FIG. 20 lies in the vertical interconnect conductive structure. The specific implementations of the steps in the embodiment related to this method may either be the same as those in FIG. 18 or those in FIG. 20. Therefore, only the steps with differences will be explained. Specifically, as shown in FIG. 22, the preparation method includes:

Operation S61: pre-preparing a support insulating material on one surface of the permanent carrier board to define a recessed chip attachment region through the support insulating material.

Operation S62: preparing on the permanent carrier board a first vertical conductive structure that penetrates the support insulating material and the permanent carrier board. This step differs from the method in FIG. 20 in that the first vertical conductive structure penetrates not only the support insulating material but also the permanent carrier board (the permanent carrier board is used as the support structure 6A in this embodiment) and the adhesive material on the permanent carrier board, with the specific effect illustrated in FIG. 6.

Operation S63: performing chip stacking on the chip attachment region of the permanent carrier board to form at least one set of stacked chips, wherein each set of stacked chips includes at least one chip with a functional surface facing the first direction and at least one chip with a functional surface facing the second direction, wherein the first direction and the second direction are opposite directions, and different chips are stacked and adhered together through a stacking material.

Operation S64: performing encapsulation encapsulate on a side of the permanent carrier board where the stacked chips are mounted with a packaging material to form a packaging material layer that encapsulates the stacked chips. In this embodiment, the packaging material layer completely encapsulates the stacked chips, the first vertical conductive structure, and the support insulating material on the side away from the permanent carrier board.

Operation S65: preparing a first conductive structure on the packaging material layer that is electrically connected to the chip with the functional surface facing the first direction.

Operation S66: preparing a second vertical conductive structure on the packaging material layer that is vertically interconnected to the first vertical conductive structure, wherein the first vertical conductive structure and the second vertical interconnect conductive structure together form a vertical interconnect conductive structure.

Operation S67: preparing a first redistribution layer on the packaging material layer that is electrically connected to the chip facing the first direction, wherein the first redistribution layer is electrically connected to the chip facing the first direction through the first conductive structure.

Operation S68: preparing a second conductive structure on the permanent carrier board that is electrically connected to the chip with a functional surface facing the second direction.

Operation S69: preparing a second redistribution layer on the permanent carrier board that is electrically connected to the first redistribution layer through the vertical interconnect conductive structure and is electrically connected to the chip with a functional surface facing the second direction through the second conductive structure.

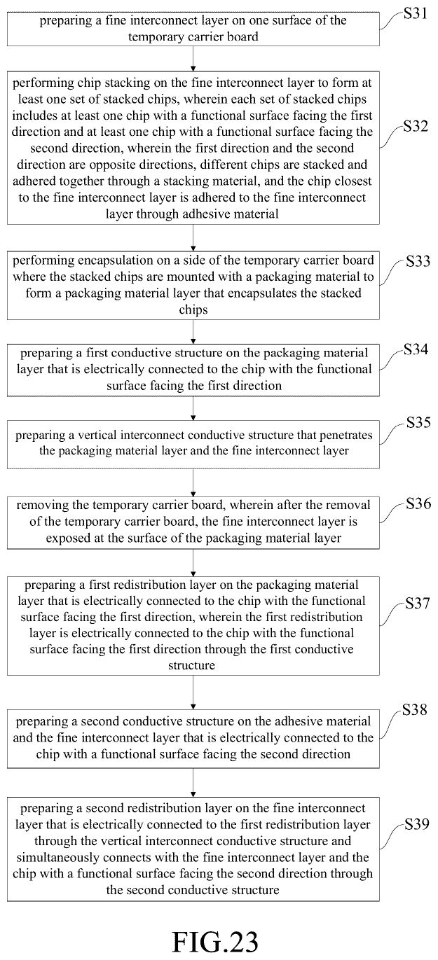

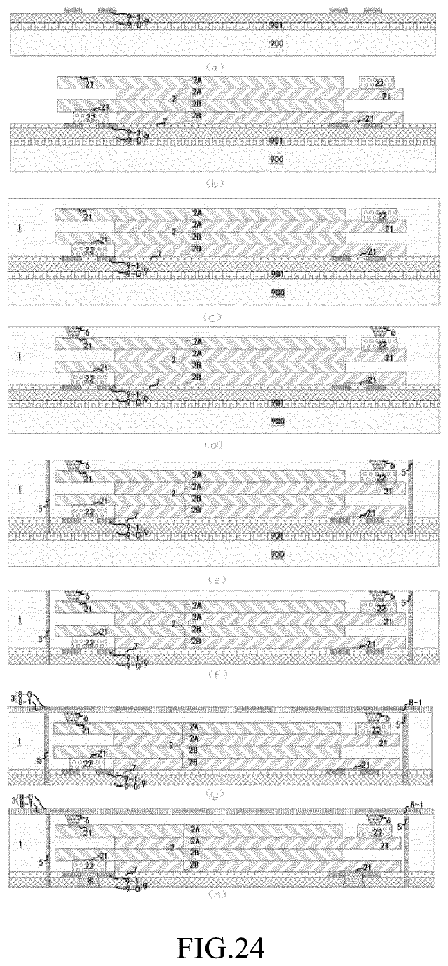

FIGS. 23 and 24 schematically illustrate a preparation method for the packaging structure shown in FIG. 3. The preparation method includes:

Operation S31: preparing a fine interconnect layer on one surface of the temporary carrier board. This can be done by directly preparing the fine interconnect layer on the removable material of the temporary carrier board or by bonding a pre-prepared fine interconnect layer onto the removable material. The intermediate structure of the packaging structure obtained through this step is shown in FIG. 24 (a), where the fine interconnect layer 9 is adhered to the removable material 901 on the temporary carrier board 900.

Operation S32: performing chip stacking on the fine interconnect layer to form at least one set of stacked chips, wherein each set of stacked chips includes at least one chip with a functional surface facing the first direction and at least one chip with a functional surface facing the second direction, wherein the first direction and the second direction are opposite directions, and different chips are stacked and adhered together through a stacking material. The chip closest to the fine interconnect layer is adhered to the fine interconnect layer through adhesive material. In this step, in addition to stacking the chips as described previously, it is important to ensure that the chip pin pads of the chips directly adhered to the fine interconnect layer and the chip pin bumps of other chips with functional surfaces facing the second direction are precisely aligned with the fine interconnect conductive structure 9-1 of the fine interconnect layer, where the correspondence can be one-to-one or one chip pin bump or one chip pin pad corresponding to two fine interconnect conductive structures with a gap in between. The intermediate structure of the packaging structure obtained through this step is shown in FIG. 24 (b).

Operation S33: performing encapsulation on a side of the temporary carrier board where the stacked chips are mounted with a packaging material to form a packaging material layer that encapsulates the stacked chips. The intermediate structure of the packaging structure obtained through this step is shown in FIG. 24 (c).

Operation S34: preparing a first conductive structure on the packaging material layer that is electrically connected to the chip with the functional surface facing the first direction. The intermediate structure of the packaging structure obtained through this step is shown in FIG. 24 (d).

Operation S35: preparing a vertical interconnect conductive structure that penetrates the packaging material layer and the fine interconnect layer. This step differs from the previous preparation methods in that the vertical interconnect conductive structure simultaneously penetrates the packaging material layer and the fine interconnect insulating material of the fine interconnect layer. The intermediate structure of the packaging structure obtained through this step is shown in FIG. 24 (e).

Operation S36: removing the temporary carrier board, wherein after the removal of the temporary carrier board, the fine interconnect layer is exposed at the surface of the packaging material layer. This step differs from the previous preparation methods in that the exposed surface of the packaging material layer includes the fine interconnect insulating material and the vertical interconnect conductive structure, with the stacked chips covered by the fine interconnect layer. The intermediate structure of the packaging structure obtained through this step is shown in FIG. 24 (f).

Operation S37: preparing a first redistribution layer on the packaging material layer that is electrically connected to the chip with the functional surface facing the first direction, wherein the first redistribution layer is electrically connected to the chip facing the first direction through the first conductive structure. The intermediate structure of the packaging structure obtained through this step is shown in FIG. 24 (g).

Operation S38: preparing a second conductive structure on the adhesive material and the fine interconnect layer that is electrically connected to the chip with a functional surface facing the second direction. Unlike the previous preparation methods, this embodiment requires the preparation of a second conductive structure that penetrates both the adhesive material and the fine interconnect layer, electrically connecting the second conductive structure with the chip with a functional surface facing the second direction. The second conductive structure can penetrate the fine interconnect conductive structure or the fine interconnect insulating material. Taking the example of penetrating the fine interconnect insulating material, based on the intermediate structure shown in FIG. 24 (g), the intermediate structure obtained through this step is shown in FIG. 24 (h), where the second conductive structure completely penetrates the fine interconnect insulating material 9-0 corresponding to the two fine interconnect conductive structures 9-1 of the same chip pin bump 22 or chip pin pad 21, electrically connecting the two adjacent fine interconnect conductive structures corresponding to the same chip pin bump or the same chip pin pad.

Operation S39: preparing a second redistribution layer on the fine interconnect layer that is electrically connected to the first redistribution layer through the vertical interconnect conductive structure and simultaneously connects with the fine interconnect layer and the chip with a functional surface facing the second direction through the second conductive structure. In this step, at least a portion of the redistribution conductive structure of the second redistribution layer needs to correspond to the vertical interconnect conductive structure, and at least a portion of the redistribution conductive structure of the second redistribution layer needs to correspond to the second conductive structure, thereby achieving electrical connectivity between the second redistribution layer and the fine interconnect layer and the chip with a functional surface facing the second direction, allowing the fine interconnect layer to also be electrically connected to the stacked chips. Through this step, the packaging structure as shown in FIG. 3 can be prepared.

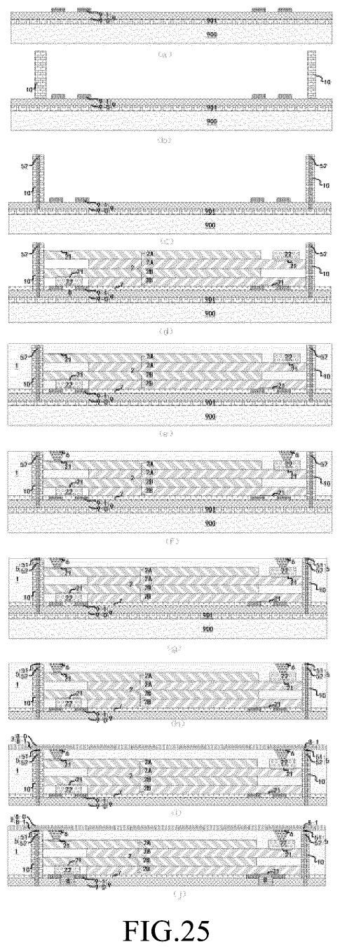

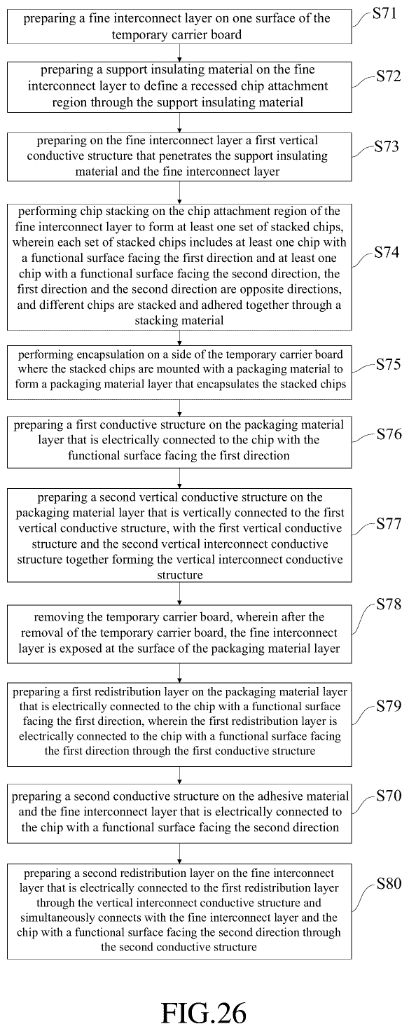

FIGS. 25 and 26 schematically illustrate the preparation method for the packaging structure shown in FIG. 7. The main difference from the method shown in FIG. 23 lies in the preparation of the vertical interconnect conductive structure. Therefore, by combining the preparation of the vertical interconnect conductive structure in FIG. 26 with the previous preparation methods, the corresponding implementation details of the steps can be obtained. Thus, the following will briefly explain the method steps related to this embodiment and the corresponding intermediate structure effects without repeating detailed explanations of each step. As shown in FIGS. 25 and 26, the preparation method includes:

Operation S71: preparing a fine interconnect layer on one surface of the temporary carrier board. The intermediate structure of the packaging structure obtained through this step is shown in FIG. 25 (a).

Operation S72: preparing a support insulating material on the fine interconnect layer to define a recessed chip attachment region through the support insulating material. The intermediate structure of the packaging structure obtained through this step is shown in FIG. 25 (b).

Operation S73: preparing on the support insulating material a first vertical conductive structure that penetrates the support insulating material and the fine interconnect layer. In this step, the difference from the previous methods lies in that the first vertical conductive structure simultaneously penetrates the support insulating material and the fine interconnect insulating material of the fine interconnect layer, resulting in the intermediate structure of the packaging structure shown in FIG. 25 (c). Of course, in other embodiments, the first vertical conductive structure that penetrates the support insulating material and the third vertical conductive structure that penetrates the fine interconnect insulating material can be prepared separately to form the vertical interconnect conductive structure with the second vertical conductive structure, which is an obvious variation that those skilled in the art can easily conceive based on the disclosure of the present invention, thus it will not be elaborated further.

Operation S74: performing chip stacking on the chip attachment region of the fine interconnect layer to form at least one set of stacked chips, wherein each set of stacked chips includes at least one chip with a functional surface facing the first direction and at least one chip with a functional surface facing the second direction, the first direction and the second direction are opposite directions, and different chips are stacked and adhered together through a stacking material. The intermediate structure of the packaging structure obtained through this step is shown in FIG. 25 (d).

Operation S75: performing encapsulation on a side of the temporary carrier board where the stacked chips are mounted with a packaging material to form a packaging material layer that encapsulates the stacked chips. The intermediate structure of the packaging structure obtained through this step is shown in FIG. 25 (e).

Operation S76: preparing a first conductive structure on the packaging material layer that is electrically connected to the chip with the functional surface facing the first direction. The intermediate structure of the packaging structure obtained through this step is shown in FIG. 25 (f).

Operation S77: preparing a second vertical conductive structure on the packaging material layer that is vertically interconnected to the first vertical conductive structure, with the first vertical conductive structure and the second vertical interconnect conductive structure together forming the vertical interconnect conductive structure. The intermediate structure of the packaging structure obtained through this step is shown in FIG. 25 (g).

Operation S78: removing the temporary carrier board, wherein after the removal of the temporary carrier board, the fine interconnect layer is exposed at the surface of the packaging material layer. The intermediate structure of the packaging structure obtained through this step is shown in FIG. 25 (h). In the implementation where the first vertical conductive structure does not penetrate the fine interconnect layer, a third vertical conductive structure vertically interconnected to the first vertical conductive structure that penetrates the fine interconnect insulating material can also be prepared after this step.

Operation S79: preparing a first redistribution layer on the packaging material layer that is electrically connected to the chip with a functional surface facing the first direction, wherein the first redistribution layer is electrically connected to the chip with a functional surface facing the first direction through the first conductive structure. The intermediate structure of the packaging structure obtained through this step is shown in FIG. 25 (i).

Operation S70: preparing a second conductive structure on the adhesive material and the fine interconnect layer that is electrically connected to the chip with a functional surface facing the second direction. The intermediate structure of the packaging structure obtained through this step is shown in FIG. 25 (j).

Operation S80: preparing a second redistribution layer on the fine interconnect layer that is electrically connected to the first redistribution layer through the vertical interconnect conductive structure and simultaneously connects with the fine interconnect layer and the chip with a functional surface facing the second direction through the second conductive structure. Through this step, the packaging structure as shown in FIG. 7 can be prepared.

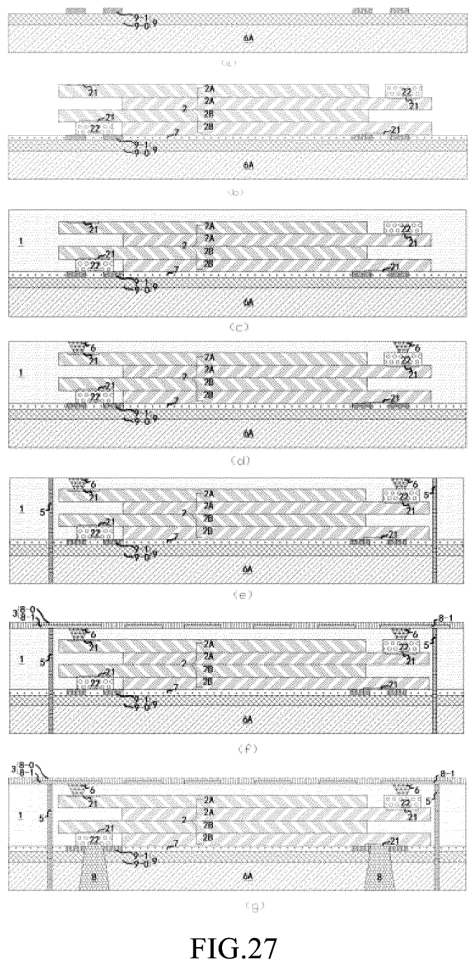

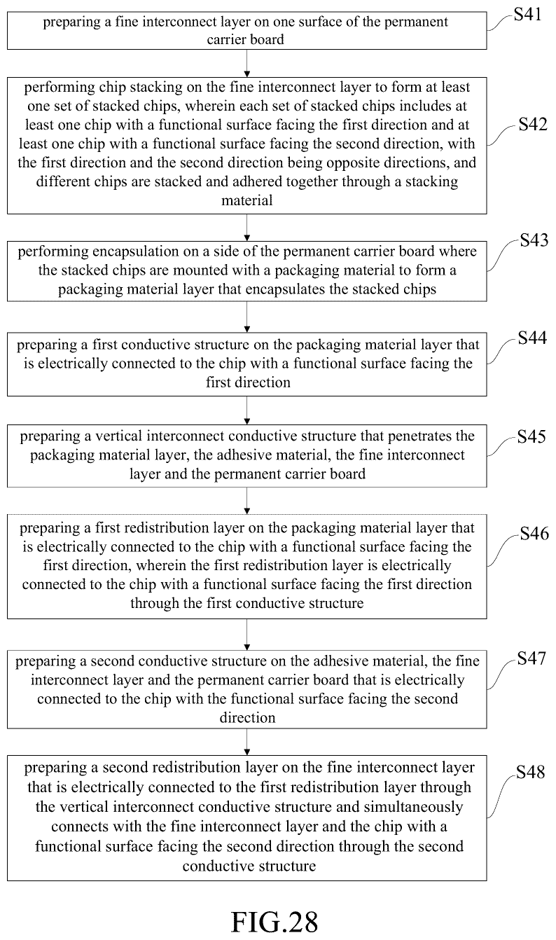

FIGS. 27 and 28 schematically illustrate the preparation method for the packaging structure shown in FIG. 4. The specific details of each step in this method can be obtained by combining the corresponding implementation details of the steps from the previous embodiments. Thus, the following will briefly explain the method steps related to this embodiment and the corresponding intermediate structure effects without repeating detailed explanations of each step. As shown in FIGS. 27 and 28, the preparation method includes:

Operation S41: preparing a fine interconnect layer on one surface of the permanent carrier board. The intermediate structure of the packaging structure obtained through this step is shown in FIG. 27 (a).

Operation S42: performing chip stacking on the fine interconnect layer to form at least one set of stacked chips, wherein each set of stacked chips includes at least one chip with a functional surface facing the first direction and at least one chip with a functional surface facing the second direction, with the first direction and the second direction being opposite directions, and different chips are stacked and adhered together through a stacking material. The intermediate structure of the packaging structure obtained through this step is shown in FIG. 27 (b).

Operation S43: performing encapsulation on a side of the permanent carrier board where the stacked chips are mounted with a packaging material to form a packaging material layer that encapsulates the stacked chips. The intermediate structure of the packaging structure obtained through this step is shown in FIG. 27 (c).

Operation S44: preparing a first conductive structure on the packaging material layer that is electrically connected to the chip with a functional surface facing the first direction. The intermediate structure of the packaging structure obtained through this step is shown in FIG. 27 (d).

Operation S45: preparing on the packaging material layer a vertical interconnect conductive structure that penetrates the packaging material layer, the adhesive material, the fine interconnect layer and the permanent carrier board. The intermediate structure of the packaging structure obtained through this step is shown in FIG. 27 (e).

Operation S46: preparing a first redistribution layer on the packaging material layer that is electrically connected to the chip facing the first direction, wherein the first redistribution layer is electrically connected to the chip facing the first direction through the first conductive structure. The intermediate structure of the packaging structure obtained through this step is shown in FIG. 27 (f).

Operation S47: preparing a second conductive structure that penetrates the permanent carrier board, the adhesive material and fine interconnect layer, electrically connecting with the chip with a functional surface facing the second direction. The position of the second conductive structure through the fine interconnect layer can be set according to the previous text. The intermediate structure of the packaging structure obtained through this step is shown in FIG. 27 (g).

Operation S48: preparing a second redistribution layer on the fine interconnect layer that is electrically connected to the first redistribution layer through the vertical interconnect conductive structure and simultaneously electrically connects with the fine interconnect layer and the chip with a functional surface facing the second direction through the second conductive structure. Through this step, the packaging structure as shown in FIG. 4 can be prepared.

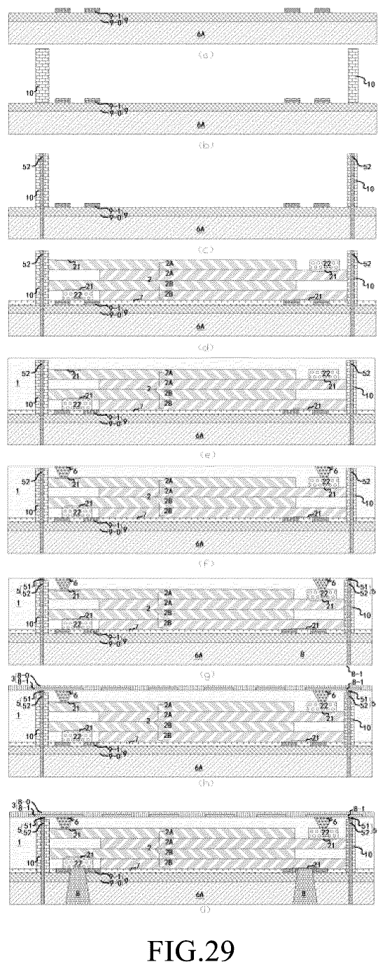

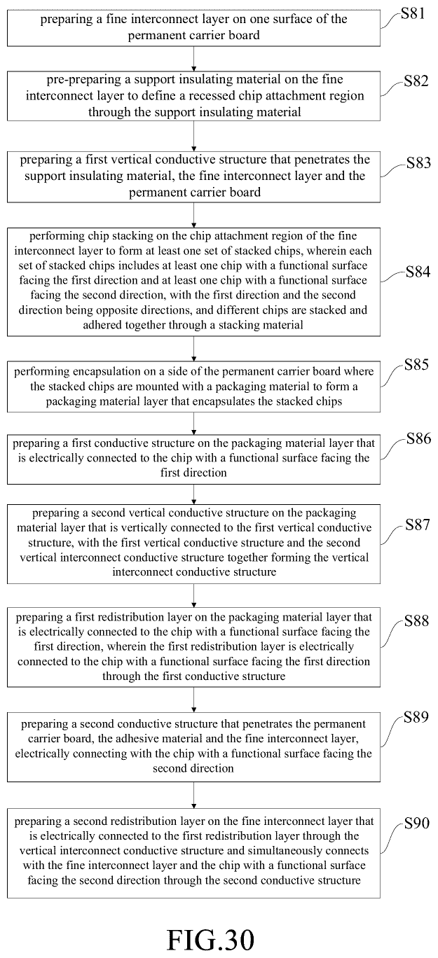

FIGS. 29 and 30 schematically illustrate the preparation method for the packaging structure shown in FIG. 8. The specific details of each step in this method can be obtained by combining the corresponding implementation details of the steps from the previous embodiments. Thus, the following will briefly explain the method steps related to this embodiment and the corresponding intermediate structure effects without repeating detailed explanations of each step. As shown in FIGS. 29 and 30, the preparation method includes:

Operation S81: preparing a fine interconnect layer on one surface of the permanent carrier board. The intermediate structure of the packaging structure obtained through this step is shown in FIG. 29 (a).

Operation S82: pre-preparing a support insulating material on the fine interconnect layer to define a recessed chip attachment region through the support insulating material. The intermediate structure of the packaging structure obtained through this step is shown in FIG. 29 (b).

Operation S83: preparing on the support insulating material a first vertical conductive structure that penetrates the support insulating material, the fine interconnect layer and the permanent carrier board. The intermediate structure of the packaging structure obtained through this step is shown in FIG. 29 (c).

Operation S84: performing chip stacking on the chip attachment region of the fine interconnect layer to form at least one set of stacked chips, wherein each set of stacked chips includes at least one chip with a functional surface facing the first direction and at least one chip with a functional surface facing the second direction, with the first direction and the second direction being opposite directions, and different chips are stacked and adhered together through a stacking material. The chip closest to the fine interconnect layer is adhered to the fine interconnect layer through adhesive material. The intermediate structure of the packaging structure obtained through this step is shown in FIG. 29 (d).

Operation S85: performing encapsulation on a side of the permanent carrier board where the stacked chips are mounted with a packaging material to form a packaging material layer that encapsulates the stacked chips. The intermediate structure of the packaging structure obtained through this step is shown in FIG. 29 (e).

Operation S86: preparing a first conductive structure on the packaging material layer that is electrically connected to the chip with a functional surface facing the first direction. The intermediate structure of the packaging structure obtained through this step is shown in FIG. 29 (f).

Operation S87: preparing a second vertical conductive structure on the packaging material layer that is vertically interconnected to the first vertical conductive structure, with the first vertical conductive structure and the second vertical interconnect conductive structure together forming the vertical interconnect conductive structure. The intermediate structure of the packaging structure obtained through this step is shown in FIG. 29 (g).

Operation S88: preparing a first redistribution layer on the packaging material layer that is electrically connected to the chip facing the first direction, wherein the first redistribution layer is electrically connected to the chip with a functional surface facing the first direction through the first conductive structure. The intermediate structure of the packaging structure obtained through this step is shown in FIG. 29 (h).

Operation S89: preparing a second conductive structure that penetrates the permanent carrier board, the adhesive material and the fine interconnect layer, electrically connecting with the chip with a functional surface facing the second direction. The position of the second conductive structure through the fine interconnect layer can be set according to the previous text. The intermediate structure of the packaging structure obtained through this step is shown in FIG. 29 (i).

Operation S90: preparing a second redistribution layer on the fine interconnect layer that is electrically connected to the first redistribution layer through the vertical interconnect conductive structure and simultaneously connects with the fine interconnect layer and the chip with a functional surface facing the second direction through the second conductive structure. Through this step, the packaging structure as shown in FIG. 8 can be prepared.

The following will describe a preparation method for the back-to-back three-dimensional stacked fan-out packaging module of the present invention.

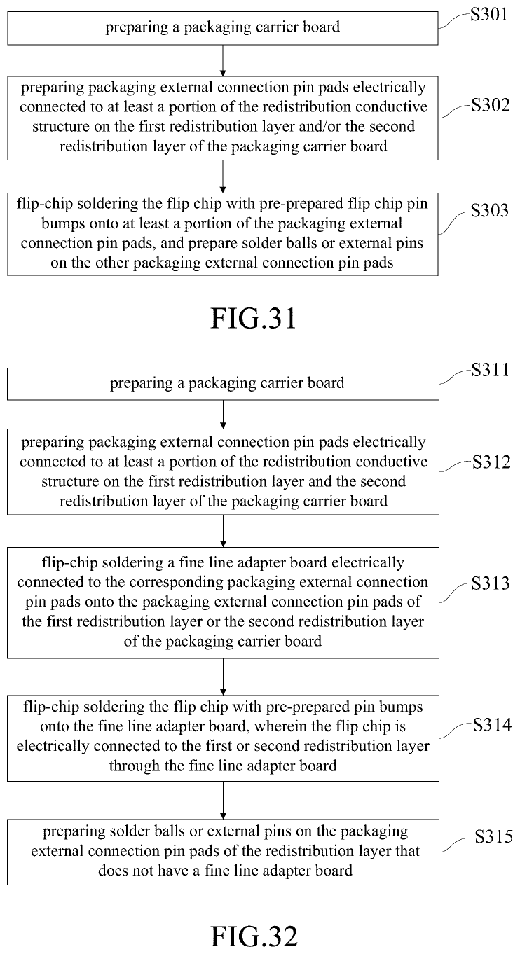

FIG. 31 schematically illustrates the preparation method for a back-to-back three-dimensional stacked fan-out packaging module according to one embodiment. As shown in FIG. 31, the method includes:

Operation S301: preparing a packaging carrier board, wherein the packaging carrier board may be prepared using the preparation method of the back-to-back three-dimensional stacked fan-out packaging structure from any of the aforementioned embodiments, and the prepared packaging carrier board including at least two sets of stacked chips.

Operation S302: preparing packaging external connection pin pads electrically connected to at least a portion of the redistribution conductive structure on the first redistribution layer and/or the second redistribution layer of the packaging carrier board.

Operation S303: flip-chip soldering the flip chip with pre-prepared flip chip pin bumps onto at least a portion of the packaging external connection pin pads, and prepare solder balls or external pins on the other packaging external connection pin pads. The flip chip is soldered onto the packaging external connection pin pads of the first redistribution layer or the second redistribution layer through flip-chip reflow soldering or TCB processes, and the density of the flip chip pin bumps on the flip chip is C4 bump or higher.

FIG. 32 schematically illustrates another embodiment of a preparation method of back-to-back three-dimensional stacked fan-out packaging structure. As shown in FIG. 32, the method includes:

Operation S311: preparing a packaging carrier board, wherein the packaging carrier board may be prepared using the preparation method of the back-to-back three-dimensional stacked fan-out packaging structure from any of the aforementioned embodiments. The prepared packaging carrier board includes at least two sets of stacked chips.

Operation S312: preparing packaging external connection pin pads electrically connected to at least a portion of the redistribution conductive structure on the first redistribution layer and the second redistribution layer of the packaging carrier board.

Operation S313: flip-chip soldering a fine line adapter board electrically connected to the corresponding packaging external connection pin pads onto the packaging external connection pin pads of the first redistribution layer or the second redistribution layer of the packaging carrier board.

Operation S314: flip-chip soldering the flip chip with pre-prepared pin bumps onto the fine line adapter board, wherein the flip chip is electrically connected to the first or second redistribution layer through the fine line adapter board.

Operation S315: preparing solder balls or external pins on the packaging external connection pin pads of the redistribution layer that does not have a fine line adapter board.

In other possible embodiments, heat dissipation enhancement structures, microchannel heat dissipation structures, and heat dissipation devices may also be disposed on the flip chip to obtain other different embodiments.

It should be noted that the order of the operation steps described in the present invention is not necessary and can be flexibly adjusted according to specific needs. In practical applications, the order of the operation steps can be adjusted accordingly, such as swapping the order of preparing the second conductive structure and preparing the first redistribution layer, etc., without affecting the effects realized by the preparation method of the present invention and the structural configuration of the resulting products.

It can be understood that in other embodiments, the steps of the preparation method described in the present invention and the features of the packaging structure can also be freely combined in other ways to obtain different types of packaging structures. The embodiments of the present invention are not intended to limit the combinations of the preparation method steps and the features of the packaging structure.

Finally, it should be noted that the above embodiments are only used to illustrate the technical solution of the present invention, but not to limit it; although the present invention has been described in detail with reference to the foregoing embodiments, a person having ordinary skill in the art should understand that the technical solutions described in the foregoing embodiments may be modified or some of the technical features may be replaced by equivalent ones; however, such modifications or replacements do not cause the essence of the corresponding technical solutions to deviate from the spirit and scope of the technical solutions in the embodiments of the present invention.

What is claimed is:

1. A back-to-back three-dimensional stacked fan-out packaging characterized by comprising:
at least one set of stacked chips, each set of stacked chips including at least one chip structure, with a functional surface facing a first direction and at least one chip with a functional surface facing a second direction, wherein the first direction and the second direction are opposite directions;
a packaging material layer, encapsulating the stacked chips;
a first redistribution layer, positioned on one side of the packaging material layer and electrically connected to the chip with the functional surface facing the first direction;
a second redistribution layer, positioned on the other side of the packaging material layer and electrically connected to the chip with the functional surface facing the second direction; and
a vertical interconnect conductive structure for electrically connecting the first redistribution layer and the second redistribution layer, wherein at least a partial section of the vertical interconnect conductive structure is disposed in the packaging material layer.

2. The packaging structure as claimed in claim 1, wherein the chips include chip pin pads, and at least some of the chip pin pads of at least some of the chips are provided with chip pin bumps, both the first redistribution layer and the second redistribution layer include a redistribution insulating material and a redistribution conductive structure;
wherein the chip pin pads and chip pin bumps of the chip with the functional surface facing the first direction are electrically connected to the redistribution conductive structure of the first redistribution layer through a first conductive structure disposed on the packaging material layer, and the second redistribution layer is arranged such that the redistribution conductive structure thereof is directly electrically connected to the chip pin pads and chip pin bumps of the chip with the functional surface facing the second direction.

3. The packaging structure as claimed in claim 1, further comprising a support structure positioned between the packaging material layer and the second redistribution layer, wherein
the stacked chips are adhered to the support structure through an adhesive material;
the chip with the functional surface facing the first direction is electrically connected to the first redistribution layer through a first conductive structure disposed on the packaging material layer;
the chip with the functional surface facing the second direction is electrically connected to the second redistribution layer through a second conductive structure that penetrates through the support structure and the adhesive material; and
the vertical interconnect conductive structure penetrates through the support structure and the adhesive material.

4. The packaging structure as claimed in claim 1, further comprising a fine interconnect layer positioned between the packaging material layer and the second redistribution layer, the fine interconnect layer including a fine interconnect insulating material and a fine interconnect conductive structure;
the stacked chips being adhered to the fine interconnect layer through an adhesive material;
the chip with the functional surface facing the first direction being electrically connected to the first redistribution layer through a first conductive structure disposed on the packaging material layer;
the chip with the functional surface facing the second direction being electrically connected to the second redistribution layer through a second conductive structure that penetrates through the fine interconnect layer and the adhesive material;
wherein the second redistribution layer is further electrically connected to the fine interconnect layer through a second conductive structure;
the vertical interconnect conductive structure penetrates through the adhesive material and the fine interconnect insulating material of the fine interconnect layer.

5. The packaging structure as claimed in claim 4, wherein the chips include chip pin pads, and at least some of the chip pin pads of at least some of the chips are provided with chip pin bumps;
wherein the chip with the functional surface facing the second direction of the stacked chips is adhered such that the chip pin pads and chip pin bumps thereof are in a one-to-one correspondence with the fine interconnect conductive structures of the fine interconnect layer, with the second conductive structure penetrating through the fine interconnect conductive structures and the adhesive material at a corresponding location of the fine interconnect layer, enabling electrical connectivity between the chip with the functional surface facing the second direction and the second redistribution layer, as well as between the second redistribution layer and the fine interconnect layer; or
the chip with the functional surface facing the second direction of the stacked chips is adhered such that each chip pin pad and chip pin bump are respectively disposed corresponding to two spaced fine interconnect conductive structures, with the second conductive structure penetrating through the fine interconnect insulating material and the adhesive material at the corresponding location of the fine interconnect layer between the two spaced fine interconnect conductive structures corresponding to the same chip pin pad or chip pin bump, enabling electrical connection between the chip with the functional surface facing the second direction and the second redistribution layer, as well as between the second redistribution layer and the fine interconnect layer; or
the chip with the functional surface facing the second direction of the stacked chips is adhered such that each chip pin pad and chip pin bump are respectively disposed corresponding to fine interconnect conductive structures of one annular structure, with the second conductive structure penetrating through the fine interconnect insulating material and the adhesive material at the corresponding location of the fine interconnect layer in the center of a ring of the fine interconnect conductive structure of the annular structure corresponding to the same chip pin pad or chip pin bump, enabling electrical connection between the chip with the functional surface facing the second direction and the second redistribution layer, as well as between the second redistribution layer and the fine interconnect layer.

6. The packaging structure as claimed in claim 4, further comprising a support structure positioned between the fine interconnect layer and the second redistribution layer, with the fine interconnect layer disposed on the support structure;
wherein the vertical interconnect conductive structure and the second conductive structure further penetrate through the support structure.

7. The packaging structure as claimed in claim 1, wherein the vertical interconnect conductive structure includes a outer ring line, which is used as a ground or signal shielding line, and a vertical conductive line positioned in the outer ring line, which is used as a conductive line.

8. The packaging structure as claimed in claim 7, further comprising a support insulating material defining a recessed chip attachment region;
wherein said at least a partial section of the vertical interconnect conductive structure is further disposed in the support insulating material, the support insulating material is encapsulated by the packaging material layer, and the height of the support insulating material is not less than the height of the stacked chips.

9. A back-to-back three-dimensional stacked fan-out packaging module, characterized by comprising:
a packaging carrier board, wherein the packaging carrier board is the back-to-back three-dimensional stacked fan-out packaging structure as claimed in claim 1, including at least two sets of stacked chips;
a flip chip, wherein the flip chip is disposed on at least a portion of the redistribution conductive structure of the first redistribution layer or the second redistribution layer of the packaging carrier board and electrically connected to the corresponding redistribution conductive structure; and
solder balls or external pins that are disposed on the first redistribution layer or the second redistribution layer and electrically connected to at least a portion of the redistribution conductive structure thereof.

10. The packaging module as claimed in claim 9, further comprising a heat dissipation enhancement structure arranged around the flip chip; and/or
a microchannel heat dissipation structure disposed on the flip chip; and/or
a heat dissipation device disposed on the redistribution layer without the flip chip.

11. The packaging module as claimed in claim 10, wherein the stacked chips are memory chips, and the flip chip is a CPU or GPU.

12. A back-to-back three-dimensional stacked fan-out packaging module, characterized by comprising:
a packaging carrier board, wherein the packaging carrier board is the back-to-back three-dimensional stacked fan-out packaging structure as claimed in claim 1, including at least two sets of stacked chips;
a fine line adapter board disposed on the first redistribution layer or the second redistribution layer of the packaging carrier board, wherein the fine line adapter board is electrically connected to the corresponding redistribution layer;
a flip chip, wherein the flip chip is disposed on the fine line adapter board and electrically connected to the fine line adapter board; and
solder balls or external pins disposed on the redistribution layer without the fine line adapter board and electrically connected to at least a portion of the redistribution conductive structure.

13. The packaging module as claimed in claim 12, wherein a heat dissipation enhancement structure is further disposed around the flip chip.

14. The packaging module as claimed in claim 13, wherein the stacked chips are memory chips, and the flip chip is a CPU or GPU.

15. A preparation method of a back-to-back three-dimensional stacked fan-out packaging structure, characterized by comprising:
performing chip stacking on one surface of a temporary carrier board to form at least one set of stacked chips, wherein each set of stacked chips includes at least one chip with a functional surface facing a first direction and at least one chip with a functional surface facing a second direction, wherein the first direction and second direction are opposite directions, and the different chips are stacked and adhered together through a stacking material;
performing encapsulation on a side of the temporary carrier board where the stacked chips are mounted with a packaging material to form a packaging material layer that encapsulates the stacked chips;
preparing a conductive structure on the packaging material layer, wherein the conductive structure include a first conductive structure that is electrically connected to the chip with the functional surface facing the first direction and a vertical interconnect conductive structure that penetrates through the packaging material layer;
removing the temporary carrier board, exposing chip surfaces that were covered by the temporary carrier board to a surface of the packaging material layer; and
preparing a first redistribution layer that is electrically connected to the chip facing the first direction and a second redistribution layer that is electrically connected to the chip facing the second direction on both surfaces of the packaging material layer, wherein the first redistribution layer is electrically connected to the chip facing the first direction through the first conductive structure, the second redistribution layer is directly electrically connected to the chip facing the second direction, and the first redistribution layer and second redistribution layer are electrically connected through the vertical interconnect conductive structure.

16. A preparation method of a back-to-back three-dimensional stacked fan-out packaging structure, characterized by comprising:
preparing a support insulating material and a first vertical conductive structure penetrating through the support insulating material on one surface of a temporary carrier board, wherein the support insulating material defines a recessed chip attachment region;
performing chip stacking on the chip attachment region of the temporary carrier board to form at least one set of stacked chips, wherein each set of stacked chips includes at least one chip with a functional surface facing a first direction and at least one chip with a functional surface facing a second direction, wherein the first direction and second direction are opposite directions, and the different chips are stacked and adhered together through a stacking material;
performing encapsulation on a side of the temporary carrier board where the stacked chips are mounted with a packaging material to form a packaging material layer that encapsulates the stacked chips;
preparing conductive structures on the packaging material layer, wherein the conductive structures include a first conductive structure that is electrically connected to the chip with the functional surface facing the first direction, and a second vertical conductive structure that is vertically interconnected to the first vertical conductive structure, wherein the first vertical conductive structure and the second vertical conductive structure together form a vertical interconnect conductive structure;
removing the temporary carrier board, exposing chip surfaces that were covered by the temporary carrier board to a surface of the packaging material layer; and
preparing a first redistribution layer that is electrically connected to the chip facing the first direction and a second redistribution layer that is electrically connected to the chip facing the second direction on both surfaces of the packaging material layer, wherein the first redistribution layer is electrically connected to the chip facing the first direction through the first conductive structure, the second redistribution layer is directly electrically connected to the chip facing the second direction, and the first redistribution layer and second redistribution layer are electrically connected through the vertical interconnect conductive structure.

17. A preparation method of a back-to-back three-dimensional stacked fan-out packaging structure, characterized by comprising:
performing chip stacking on one surface of a support structure to form at least one set of stacked chips, wherein each set of stacked chips includes at least one chip with a functional surface facing a first direction and at least one chip with a functional surface facing a second direction, wherein the first direction and second direction are opposite directions, and the different chips are stacked and adhered together through a stacking material;
performing encapsulation on a side of the support structure where the stacked chips are mounted with a packaging material to form a packaging material layer that encapsulates the stacked chips;
preparing a first conductive structure on the packaging material layer that is electrically connected to the chip facing the first direction;
preparing a vertical interconnect conductive structure that penetrates through the packaging material layer and the support structure;
preparing a first redistribution layer on the packaging material layer that is electrically connected to the chip facing the first direction, wherein the first redistribution layer is electrically connected to the chip facing the first direction through the first conductive structure;
preparing a second conductive structure on the support structure that is electrically connected to the chip with the functional surface facing the second direction; and
preparing a second redistribution layer on the support structure that is electrically connected to the first redistribution layer through the vertical interconnect conductive structure and is electrically connected to the chip with the functional surface facing the second direction through the second conductive structure.

18. A preparation method of a back-to-back three-dimensional stacked fan-out packaging structure, characterized by comprising:
preparing support a support insulating material and a first vertical conductive structure penetrating through the support insulating material and the support structure on one surface of the support structure, wherein the support insulating material defines a recessed chip attachment region;
performing chip stacking on the chip attachment region of the support structure to form at least one set of stacked chips, wherein each set of stacked chips includes at least one chip with a functional surface facing a first direction and at least one chip with a functional surface facing a second direction, wherein the first direction and second direction are opposite directions, and the different chips are stacked and adhered together through a stacking material;
performing encapsulation on a side of the support structure where the stacked chips are mounted with a packaging material to form a packaging material layer that encapsulates the stacked chips;
preparing a first conductive structure on the packaging material layer that is electrically connected to the chip facing the first direction;
preparing a second vertical conductive structure that is vertically interconnected to the first vertical conductive structure, wherein the first vertical conductive structure and the second vertical conductive structure together form a vertical interconnect conductive structure;
preparing a first redistribution layer on the packaging material layer that is electrically connected to the chip facing the first direction, wherein the first redistribution layer is electrically connected to the chip facing the first direction through the first conductive structure;
preparing a second conductive structure on the support structure that is electrically connected to the chip with the functional surface facing the second direction; and
preparing a second redistribution layer on the support structure that is electrically connected to the first redistribution layer through the vertical interconnect conductive structure and is electrically connected to the chip with the functional surface facing the second direction through the second conductive structure.

19. A preparation method of a back-to-back three-dimensional stacked fan-out packaging structure, characterized by comprising:
preparing a fine interconnect layer on one surface of a temporary carrier board;
performing chip stacking on the fine interconnect layer to form at least one set of stacked chips, wherein each set of stacked chips includes at least one chip with a functional surface facing a first direction and at least one chip with a functional surface facing a second direction, wherein the first direction and second direction are opposite directions, the different chips are stacked and adhered together through a stacking material, and the chip closest to the fine interconnect layer is adhered to the fine interconnect layer through an adhesive material;
performing encapsulation on a side of the temporary carrier board where the stacked chips are mounted with a packaging material to form a packaging material layer that encapsulates the stacked chips;
preparing a first conductive structure on the packaging material layer that is electrically connected to the chip facing the first direction;
preparing a vertical interconnect conductive structure that penetrates through the packaging material layer, the adhesive material and the fine interconnect layer;
removing the temporary carrier board, exposing the fine interconnect layer that was covered by the temporary carrier board to the surface of the packaging material layer;
preparing a first redistribution layer on the packaging material layer that is electrically connected to the chip facing the first direction, wherein the first redistribution layer is electrically connected to the chip facing the first direction through the first conductive structure;
preparing a second conductive structure on the adhesive material and the fine interconnect layer that is electrically connected to the chip with the functional surface facing the second direction; and
preparing a second redistribution layer on the fine interconnect layer that is electrically connected to the first redistribution layer through the vertical interconnect conductive structure and electrically connected to the fine interconnect layer and the chip with the functional surface facing the second direction through the second conductive structure.

20. A preparation method of a back-to-back three-dimensional stacked fan-out packaging structure, characterized by comprising:
preparing a fine interconnect layer on one surface of a temporary carrier board;
preparing on the fine interconnect layer a support insulating material and a first vertical conductive structure penetrating through the support insulating material and the fine interconnect layer, wherein the support insulating material defines a recessed chip attachment region;
performing chip stacking on the chip attachment region of the fine interconnect layer to form at least one set of stacked chips, wherein each set of stacked chips includes at least one chip with a functional surface facing a first direction and at least one chip with a functional surface facing a second direction, wherein the first direction and second direction are opposite directions, the different chips are stacked and adhered together through a stacking material, and the chip closest to the fine interconnect layer is adhered to the fine interconnect layer through an adhesive material;
performing encapsulation on a side of the temporary carrier board where the stacked chips are mounted with a packaging material to form a packaging material layer that encapsulates the stacked chips;
preparing a conductive structure on the packaging material layer, wherein the conductive structure include a first conductive structure that is electrically connected to the chip with the functional surface facing the first direction, and a second vertical conductive structure that is vertically interconnected to the first vertical conductive structure, wherein the first vertical conductive structure and the second vertical conductive structure together form a vertical interconnect conductive structure;
removing the temporary carrier board, exposing the fine interconnect layer that was covered by the temporary carrier board to the surface of the packaging material layer;
preparing a first redistribution layer on the packaging material layer that is electrically connected to the chip facing the first direction, wherein the first redistribution layer is electrically connected to the chip facing the first direction through the first conductive structure;
preparing a second conductive structure on the adhesive material and the fine interconnect layer that is electrically connected to the chip with the functional surface facing the second direction; and
preparing a second redistribution layer on the fine interconnect layer that is electrically connected to the first redistribution layer through the vertical interconnect conductive structure and electrically connected to the fine interconnect layer and the chip with the functional surface facing the second direction through the second conductive structure.

21. A preparation method of a back-to-back three-dimensional stacked fan-out packaging structure, characterized by comprising:
preparing a fine interconnect layer on one surface of a support structure;
performing chip stacking on the fine interconnect layer to form at least one set of stacked chips, wherein each set of stacked chips includes at least one chip with a functional surface facing a first direction and at least one chip with a functional surface facing a second direction, wherein the first direction and second direction are opposite directions, the different chips are stacked and adhered together through a stacking material, and the chip closest to the fine interconnect layer is adhered to the fine interconnect layer through an adhesive material;
performing encapsulation on a side of the support structure where the stacked chips are mounted with a packaging material to form a packaging material layer that encapsulates the stacked chips;
preparing a first conductive structure on the packaging material layer that is electrically connected to the chip facing the first direction;
preparing a vertical interconnect conductive structure that penetrates through the packaging material layer, the adhesive material, the fine interconnect layer, and the support structure;
preparing a first redistribution layer on the packaging material layer that is electrically connected to the chip facing the first direction, wherein the first redistribution layer is electrically connected to the chip facing the first direction through the first conductive structure;
preparing a second conductive structure on the support structure that is electrically connected to the chip with the functional surface facing the second direction; and
preparing a second redistribution layer on the support structure that is electrically connected to the first redistribution layer through the vertical interconnect conductive structure and electrically connected to the chip with the functional surface facing the second direction through the second conductive structure.

22. A preparation method of a back-to-back three-dimensional stacked fan-out packaging structure, characterized by comprising:
preparing a fine interconnect layer on one surface of a support structure;
preparing a support insulating material and a first vertical conductive structure penetrating through the support structure, the support insulating material and the fine interconnect layer on the fine interconnect layer, wherein the support insulating material defines a recessed chip attachment region;
performing chip stacking on the chip attachment region of the support structure to form at least one set of stacked chips, wherein each set of stacked chips includes at least one chip with a functional surface facing a first direction and at least one chip with a functional surface facing a second direction, wherein the first direction and second direction are opposite directions, the different chips are stacked and adhered together through a stacking material, and the chip closest to the fine interconnect layer is adhered to the fine interconnect layer through an adhesive material;
performing encapsulation on a side of the support structure where the stacked chips are mounted with a packaging material to form a packaging material layer that encapsulates the stacked chips;
preparing conductive structure on the packaging material layer, wherein the conductive structure include a first conductive structure that is electrically connected to the chip with the functional surface facing the first direction, and a second vertical conductive structure that is vertically interconnected to the first vertical conductive structure, wherein the first vertical conductive structure and the second vertical conductive structure together form a vertical interconnect conductive structure;
preparing a first redistribution layer on the packaging material layer that is electrically connected to the chip facing the first direction, wherein the first redistribution layer is electrically connected to the chip facing the first direction through the first conductive structure;
preparing a second conductive structure on the support structure that is electrically connected to the chip with the functional surface facing the second direction; and
preparing on the support structure a second redistribution layer that is electrically connected to the first redistribution layer through the vertical interconnect conductive structure and electrically connected to the chip with the functional surface facing the second direction through the second conductive structure.

23. A preparation method of a back-to-back three-dimensional stacked fan-out packaging module, characterized by comprising:
preparing a back-to-back three-dimensional stacked fan-out packaging structure as a packaging carrier board, wherein the prepared packaging carrier board includes at least two sets of stacked chips;
preparing, on the first redistribution layer and/or the second redistribution layer of the packaging carrier board, packaging external connection pin pads that are electrically connected to at least a portion of the redistribution conductive structure thereof; and
flip-chip soldering a flip chip pre-prepared with pad bumps on at least some of the packaging external connection pin pads and preparing solder balls or external pins on the other packaging external connection pin pads.

24. A preparation method of a back-to-back three-dimensional stacked fan-out packaging module, characterized by comprising:
preparing a back-to-back three-dimensional stacked fan-out packaging structure as a packaging carrier board, wherein the prepared packaging carrier board includes at least two sets of stacked chips;
preparing, on the first redistribution layer and the second redistribution layer of the packaging carrier board, packaging external connection pin pads that are electrically connected to at least a portion of the redistribution conductive structure thereof;
flip-chip soldering a fine line adapter board, which is electrically connected to the corresponding packaging external connection pin pads, on the packaging external connection pin pads of the first redistribution layer or the second redistribution layer of the packaging carrier board;
flip-chip soldering a flip chip pre-prepared with pad bumps on the fine line adapter board, wherein the flip chip is electrically connected to the first or second redistribution layer through the fine line adapter board; and
preparing solder balls or external pins on the packaging external connection pin pads on the redistribution layer that does not have the fine line adapter board.
